(19) United States
(12) Patent Application Publication
(10) Pub. No.: US 2026/0059756 A1
(43) Pub. Date: Feb. 26, 2026

(54) SEMICONDUCTOR DEVICE AND METHOD OF MANUFACTURING THE SAME

(71) Applicant: Samsung Electronics Co., Ltd., Suwon-si (KR)

(72) Inventor: Kang Lib Kim, Suwon-si (KR)

(21) Appl. No.: 19/238,984

(22) Filed: Jun. 16, 2025

(30) Foreign Application Priority Data
Aug. 22, 2024 (KR) 10-2024-0113103

(51) Int. Cl. H10B 43/27; H10B 41/10; H10B 41/27; H10B 41/41; H10B 43/10; H10B 43/40

(52) U.S. Cl. CPC H10B 43/27; H10B 41/10; H10B 41/27; H10B 41/41; H10B 43/10; H10B 43/40

(57) ABSTRACT

A semiconductor device manufacturing method includes forming a mold stack by alternately forming sacrificial and molding layers on a substrate, forming a photoresist pattern on the mold stack while exposing portions of the mold stack, and removing the portions of the mold stack to form contact plug holes extending into the mold stack. The contact plug holes include first contact plug holes arranged apart from each other by a first distance, and second contact plug holes arranged apart from each other by a second distance not less than the first distance. The second contact plug holes are apart from the first contact plug holes by a third distance less than the first distance. The removing includes selectively removing the portions of the mold stack to simultaneously form contact plug holes arranged apart from each other by at least the first distance among the first and second contact plug holes.

### CROSS-REFERENCE TO RELATED APPLICATION

This application is based on and claims priority under 35 U.S. C. § 119 to Korean Patent Application No. 10-2024-0113103, filed on Aug. 22, 2024, in the Korean Intellectual Property Office, the disclosure of which is incorporated by reference herein in its entirety.

### BACKGROUND

Embodiments of the inventive concept relate to a semiconductor device and a method of manufacturing the semiconductor device, and more particularly, to a semiconductor device having vertical channels and a method of manufacturing the semiconductor device.

Semiconductor devices capable of storing large amounts of data are needed for electronic systems requiring data storage. Therefore, research to increase the data storage capacity of semiconductor devices has been conducted. For example, semiconductor devices including memory cells arranged three-dimensionally instead of memory cells arranged two-dimensionally have been proposed to increase the data storage capacity of semiconductor devices.

### SUMMARY

Embodiments of the inventive concept provide a semiconductor device with improved integration density and electrical characteristics and a method of manufacturing the semiconductor device.

The technical idea of the inventive concept is not limited thereto, and other aspects of the inventive concept will be apparently understood by those skilled in the art through the following description.

According to an aspect of the inventive concept, there is provided a method of manufacturing a semiconductor device, the method including forming a mold stack by alternately forming a plurality of sacrificial layers and a plurality of mold insulating layers on a substrate, forming a photoresist pattern on the mold stack while exposing portions of the mold stack, and removing the portions of the mold stack exposed through the photoresist pattern to form a plurality of contact plug holes extending into the mold stack. The plurality of contact plug holes extend in a direction perpendicular to a horizontal plane. The plurality of contact plug holes include a plurality of first contact plug holes arranged apart from each other by a first distance in the horizontal plane, and a plurality of second contact plug holes arranged apart from each other by a second distance greater than or equal to the first distance in the horizontal plane. The plurality of second contact plug holes are arranged apart from the plurality of first contact plug holes by a third distance less than the first distance in the horizontal plane. In the removing of the portions of the mold stack, the portions of the mold stack are selectively removed such that a plurality of contact plug holes arranged apart from each other by at least the first distance in the horizontal plane are simultaneously formed among the plurality of first contact plug holes and the plurality of second contact plug holes.

According to another aspect of the inventive concept, there is provided a method of manufacturing a semiconductor device, the method including forming a mold stack by alternately forming a plurality of sacrificial layers and a plurality of mold insulating layers on a substrate, forming a photoresist pattern on the mold stack while exposing portions of the mold stack, and removing the portions of the mold stack exposed through the photoresist pattern to form a plurality of contact plug holes extending into the mold stack. The plurality of contact plug holes extending in a direction perpendicular to a horizontal plane. The plurality of contact plug holes include a plurality of first contact plug holes arranged apart from each other by a first distance in the horizontal plane, and a plurality of second contact plug holes arranged apart from each other by a second distance greater than or equal to the first distance in the horizontal plane. The plurality of second contact plug holes are arranged apart from the plurality of first contact plug holes by a third distance less than the first distance in the horizontal plane. The removing of the portions of the mold stack includes removing the portions of the mold stack to simultaneously form the plurality of first contact plug holes and the plurality of second contact plug holes to a preset height, and selectively removing the portions of the mold stack to simultaneously extend a plurality of contact plug holes that are arranged apart from each other by at least the first distance in the horizontal plane among the plurality of first contact plug holes and the plurality of second contact plug holes having the preset height.

According to another aspect of the inventive concept, there is provided a semiconductor device including a peripheral circuit structure and a cell structure on the peripheral circuit structure and including a cell region and a connection region. The cell structure includes a plurality of gate electrodes and a plurality of mold insulating layers that are alternately arranged in the cell region and the connection region in a first direction perpendicular to an upper surface of the peripheral circuit structure, a channel structure extending through the plurality of gate electrodes in the first direction, and a plurality of contact plugs electrically connected to the plurality of gate electrodes in the connection region. The plurality of contact plugs include a plurality of first contact plugs arranged apart from each other by a first distance in a horizontal plane parallel to the upper surface of the peripheral circuit structure, and a plurality of second contact plugs arranged apart from each other by a second distance greater than or equal to the first distance in the horizontal plane. The plurality of second contact plugs are arranged apart from the plurality of first contact plugs by a third distance less than the first distance in the horizontal plane.

### BRIEF DESCRIPTION OF THE DRAWINGS

Embodiments will be more clearly understood from the following detailed description taken in conjunction with the accompanying drawings in which:

FIG. 1 is a block diagram illustrating a semiconductor device according to example embodiments;

FIG. 2 is an equivalent circuit diagram illustrating a memory cell array of a semiconductor device according to example embodiments;

FIG. 3 is a perspective diagram illustrating a representative structure of a semiconductor device according to example embodiments;

FIG. 4 is a plan diagram illustrating the semiconductor device shown in FIG. 3;

FIG. 5 is a cross-sectional view taken along line A-A′ of FIG. 4;

FIG. 6A is an enlarged diagram illustrating a portion EX1 of FIG. 4;

FIG. 6B is an enlarged diagram illustrating a portion EX2 of FIG. 5;

FIGS. 7, 8, 9A, 9B, 10A, 10B, 11A, 11B, and 12 to 14 are diagrams illustrating a method of manufacturing a semiconductor device according to example embodiments, wherein FIGS. 7, 8, 9B, 10B, 11B, 12, 13, and 14 are enlarged cross-sectional diagrams corresponding to the portion EX2 of FIG. 5, and FIGS. 9A, 10A, and 10B are enlarged plan diagrams corresponding to the portion EX1 of FIG. 4;

FIG. 15A is an enlarged diagram corresponding to the portion EX1 of FIG. 4 and illustrates a method of manufacturing a semiconductor device according to example embodiments;

FIG. 15B is an enlarged cross-sectional diagram corresponding to the portion EX2 of FIG. 5 and illustrates a method of manufacturing a semiconductor device according to example embodiments;

FIG. 16A is an enlarged diagram corresponding to the portion EX1 of FIG. 4 and illustrates a layout of contact plugs of a semiconductor device according to example embodiments;

FIGS. 16B to 16D are enlarged plan diagrams corresponding to the portion EX1 of FIG. 4 and illustrate a method of manufacturing a semiconductor device according to example embodiments;

FIG. 17A is an enlarged diagram corresponding to the portion EX1 of FIG. 4 and illustrates a layout of contact plugs of a semiconductor device according to example embodiments;

FIGS. 17B to 17D are enlarged plan diagrams corresponding to the portion EX1 of FIG. 4 and illustrate a method of manufacturing a semiconductor device according to example embodiments;

FIG. 18A is an enlarged diagram corresponding to the portion EX1 of FIG. 4 and illustrates a layout of contact plugs of a semiconductor device according to example embodiments; and

FIGS. 18B to 18D are enlarged plan diagrams corresponding to the portion EX1 of FIG. 4 and illustrate a method of manufacturing a semiconductor device according to example embodiments.

### DETAILED DESCRIPTION OF THE EMBODIMENTS

Hereinafter, example embodiments will be described with reference to the accompanying drawings. In the drawings, like reference numerals denote like elements, and repeated descriptions thereof are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first,” “second,” etc. may be used herein to describe various elements or components, these elements or components should not be limited by these terms. These terms are only used to distinguish one element or component from another element or component, It is noted that aspects described with respect to one embodiment may be incorporated in different embodiments although not specifically described relative thereto. That is, all embodiments and/or features of any embodiments can be combined in any way and/or combination.

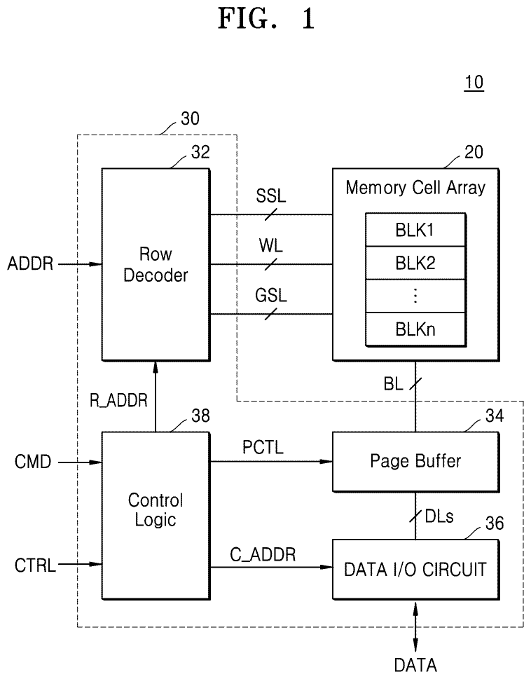

FIG. 1 is a block diagram illustrating a semiconductor device 10 according to example embodiments.

Referring to FIG. 1, the semiconductor device 10 may include a memory cell array 20, and a peripheral circuit 30. The memory cell array 20 may include a plurality of memory cell blocks BLK1, BLK2, . . . , and BLKn. Each of the plurality of memory cell blocks BLK1, BLK2, . . . , and BLKn includes a plurality of memory cells. The memory cell blocks BLK1, BLK2, . . . , and BLKn may be connected to the peripheral circuit 30 through bit lines BL, word lines WL, string selection lines SSL, and ground selection lines GSL.

The peripheral circuit 30 may include a row decoder 32, a page buffer 34, a data input/output (I/O) circuit 36, and control logic 38. Although not shown in FIG. 1, the peripheral circuit 30 may further include an I/O interface, column logic, a voltage generator, a pre-decoder, a temperature sensor, a command decoder, an address decoder, an amplification circuit, or the like.

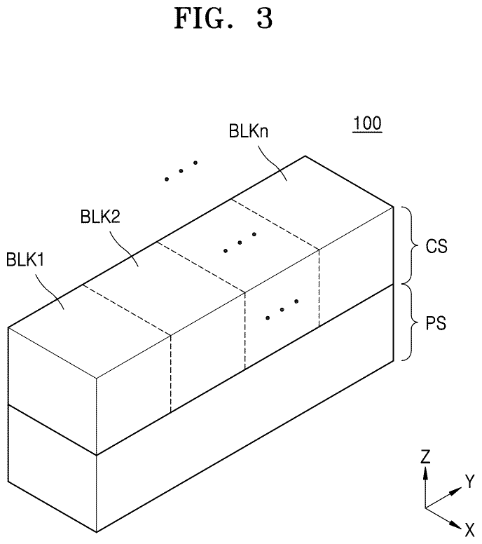

The memory cell array 20 may be connected to the page buffer 34 through the bit lines BL and to the row decoder 32 through the word lines WL, the string selection lines SSL, and the ground selection lines GSL. In the memory cell array 20, each of the memory cells included in the memory cell blocks BLK1, BLK2, . . . , and BLKn may be or may include a flash memory cell. The memory cell array 20 may include a three-dimensional memory cell array. The three-dimensional memory cell array may include a plurality of NAND strings, and each of the NAND strings may include a plurality of memory cells connected to a plurality of word lines WL that are vertically stacked, i.e., the Z-direction of FIG. 3.

The peripheral circuit 30 may receive an address ADDR, a command CMD, and a control signal CTRL from the outside of or external to the semiconductor device 10, and may transmit and receive data DATA to and/or from a device located outside the semiconductor device 10.

The row decoder 32 may select at least one memory cell block from the memory cell blocks BLK1, BLK2, . . . , and BLKn in response to the address ADDR received from the outside of or external to the semiconductor device 10, and may select a word line WL, a string selection line SSL, and a ground selection line GSL of the selected memory cell block. The row decoder 32 may transmit a voltage to the word line WL of the selected memory cell block to perform a memory operation.

The page buffer 34 may be connected to the memory cell array 20 through the bit lines BL. During a program operation, the page buffer 34 may operate as a write driver by applying, to the bit lines BL, a voltage corresponding to data DATA to be stored in the memory cell array 20. During a read operation, the page buffer 34 may operate as a sense amplifier by sensing data DATA stored in the memory cell array 20. The page buffer 34 may operate in response to a control signal PCTL received from the control logic 38.

The data I/O circuit 36 may be connected to the page buffer 34 through a plurality of data lines DLs. During a program operation, the data I/O circuit 36 may receive data DATA from a memory controller (not shown) and may provide program data DATA to the page buffer 34 based on a column address C_ADDR received from the control logic 38. During a read operation, the data I/O circuit 36 may provide read data DATA stored in the page buffer 34 to the memory controller based on a column address C_ADDR received from the control logic 38.

The data I/O circuit 36 may transmit an input address ADDR or instruction to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and a column address C_ADDR to the data I/O circuit 36. The control logic 38 may generate, in response to the control signal CTRL, various internal control signals that are to be used in the semiconductor device 10. For example, during a memory operation such as a program operation and/or an erase operation, the control logic 38 may adjust voltage levels that are to be provided to word lines WL and bit lines BL.

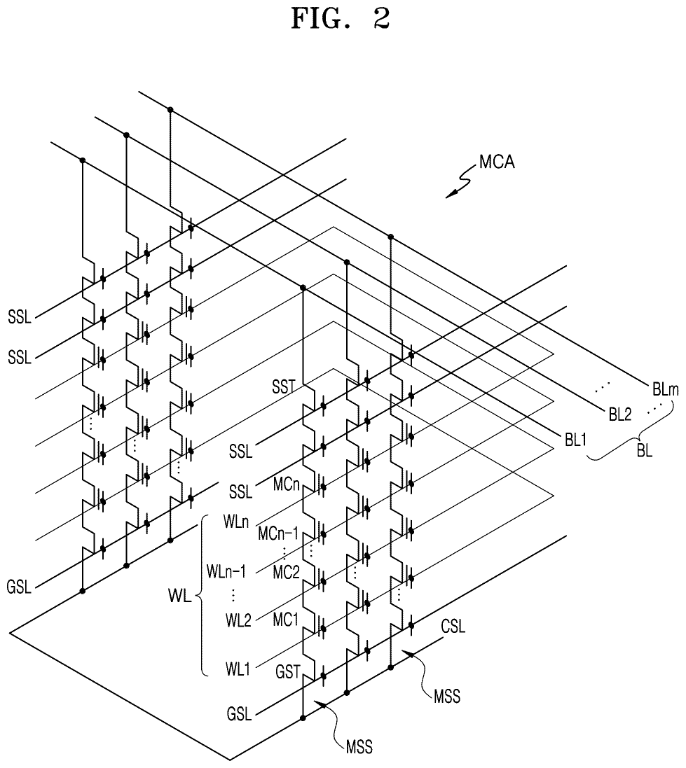

FIG. 2 is an equivalent circuit diagram illustrating a memory cell array MCA of the semiconductor device 10 according to example embodiments.

Referring to FIG. 2, the memory cell array MCA may include a plurality of memory cell strings MSS. The memory cell array MCA may include a plurality of bit lines BL: BL1, BL2, . . . , and BLm, a plurality of word lines WL: WL1, WL2, . . . , WLn−1, and WLn, at least one string selection line SSL, at least one ground selection line GSL, and a common source line CSL. The memory cell strings MSS may be formed between the bit lines BL: BL1, BL2, . . . , and BLm and the common source line CSL. Although FIG. 2 illustrates an example in which each of the memory cell strings MSS includes one ground selection line GSL and two string selection lines SSL, the embodiments of the inventive concept are not limited thereto. For example, each of the memory cell strings MSS may include one string selection line SSL.

Each of the memory cell strings MSS may include a string selection transistor SST, a ground selection transistor GST, and a plurality of memory cell transistors MC1, MC2, . . . , MCn−1, and MCn. A drain region of the string selection transistor SST may be connected to a bit line BL: BL1, BL2, . . . , or BLm, and a source region of the ground selection transistor GST may be connected to the common source line CSL. The common source line CSL may be a region to which source regions of a plurality of ground selection transistors GST are connected in common.

The string selection transistor SST may be connected to a string selection line SSL, and the ground selection transistor GST may be connected to a ground selection line GSL. Each of the memory cell transistors MC1, MC2, . . . , MCn−1, and MCn may be respectively connected to word lines WL: WL1, WL2, . . . , WLn−1, and WLn.

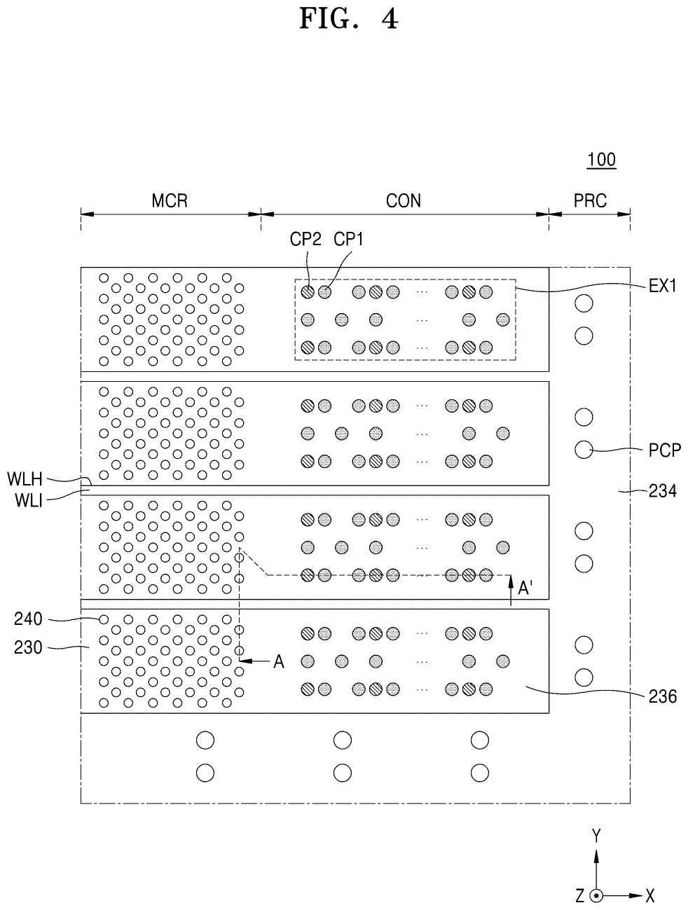

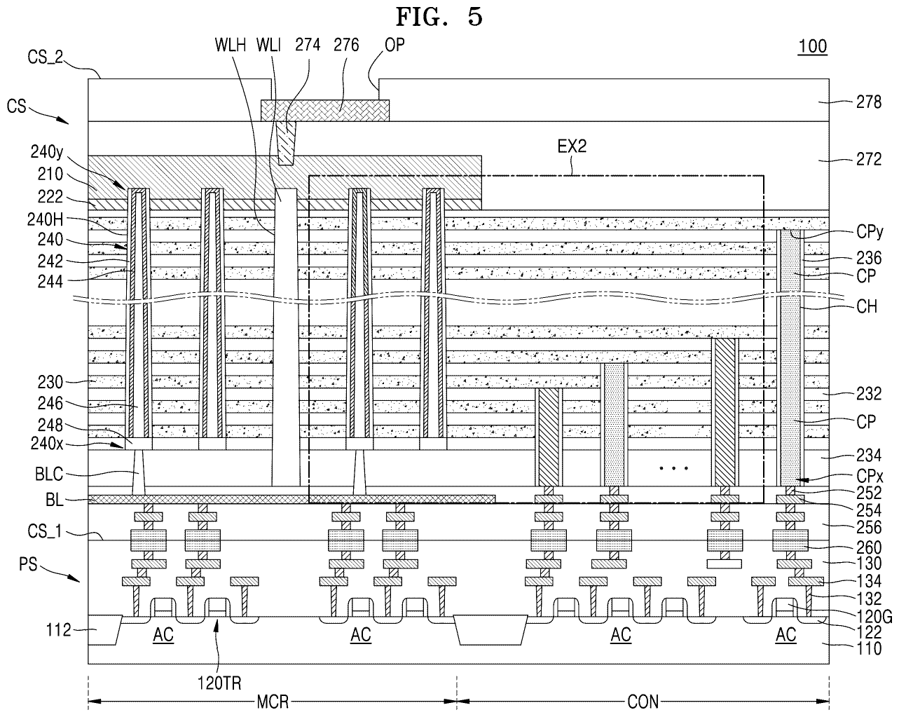

FIG. 3 is a perspective diagram illustrating a representative structure of a semiconductor device 100 according to example embodiments. FIG. 4 is a plan diagram illustrating the semiconductor device 100 shown in FIG. 3. FIG. 5 is a cross-sectional view taken along line A-A′ of FIG. 4.

Referring to FIGS. 3 to 5, the semiconductor device 100 may include a cell structure CS and a peripheral circuit structure PS that overlap each other in a vertical direction Z. The cell structure CS may include the memory cell array 20 described with reference to FIG. 1, and the peripheral circuit structure PS may include the peripheral circuit 30 described with reference to FIG. 1.

The cell structure CS may include a plurality of memory cell blocks BLK1, BLK2, . . . , BLKn. Each of the memory cell blocks BLK1, BLK2, . . . , BLKn may include memory cells that are three-dimensionally arranged.

The peripheral circuit structure PS may include peripheral circuit transistors 120TR arranged on a substrate 110. Active regions AC may be defined in the substrate 110 by a device isolation layer 112, and the peripheral circuit transistors 120TR may be formed in the active regions AC. The peripheral circuit transistors 120TR may each include a peripheral circuit gate 120G and source/drain regions 122 arranged in the substrate 110 on both sides of the peripheral circuit gate 120G.

The substrate 110 may include a semiconductor material such as a Group IV semiconductor, a Group III-V compound semiconductor, and/or a Group II-VI oxide semiconductor. For example, the Group IV semiconductor may include silicon (Si), germanium (Ge), or silicon-germanium. The substrate 110 may be provided as a bulk wafer or an epitaxial layer. In other embodiments, the substrate 110 may include a silicon-on-insulator (SOI) substrate or a germanium-on-insulator (GeOI) substrate.

A plurality of peripheral circuit contacts 132 and a plurality of peripheral circuit wiring layers 134 may be arranged above (Z-direction) an upper surface of the substrate 110. An interlayer insulating layer 130 may be disposed on the substrate 110 to be on and at least partially cover the peripheral circuit transistors 120TR, the peripheral circuit contacts 132, and the peripheral circuit wiring layers 134. The peripheral circuit wiring layers 134 may have a multilayer structure including a plurality of metal layers disposed at different vertical (Z-direction) levels. Connection pads 260 may be arranged on the interlayer insulating layer 130, and the peripheral circuit structure PS and the cell structure CS may be electrically connected and bonded to each other through the connection pads 260.

The cell structure CS may include a cell region MCR, a connection region CON, and a peripheral circuit connection region PRC. The cell region MCR may be a region in which memory cell blocks BLK each including a plurality of memory cell strings extending in the vertical direction Z are arranged. A common source layer 210, a plurality of gate electrodes 230, and channel structures 240 extending in the vertical direction Z through the gate electrodes 230 and connected to the common source layer 210 may be arranged in the cell region MCR. The gate electrodes 230 and a plurality of contact plugs CP respectively and electrically connected to the gate electrodes 230 may be arranged in the connection region CON. Peripheral plugs PCP, extending in the vertical direction Z and electrically connected to the peripheral circuit wiring layers 134, may be arranged in the peripheral circuit connection region PCR.

The cell structure CS may include a first side CS_1 connected to the peripheral circuit structure PS and a second side CS_2 that is opposite the first side CS_1. FIG. 5 illustrates that the first side CS_1 of the cell structure CS is on a lower side of the cell structure CS, and the second side CS_2 of the cell structure CS is on an upper side of the cell structure CS.

The gate electrodes 230 may be arranged apart from each other in the vertical direction Z in the cell region MCR and the connection region CON and may be alternately arranged with mold insulating layers 232. The gate electrodes 230, arranged apart from each other in the vertical direction Z, may have the same width in a first horizontal direction X.

In example embodiments, the gate electrodes 230 may include a metal such as tungsten, nickel, cobalt, and/or tantalum; a metal silicide such as tungsten silicide, nickel silicide, cobalt silicide, and/or tantalum silicide; doped polysilicon; or a combination thereof.

In example embodiments, the gate electrodes 230 may correspond to ground selection lines GSL, word lines WL1 to WLn, and one or more string selection lines SSL that form memory cell strings MSS (refer to FIG. 2). For example, an uppermost gate electrode 230 may function as the ground selection lines GSL, lowermost two gate electrodes 230 may function as the string selection lines SSL, and the remaining gate electrodes 230 may function as the word lines WL1 to WLn. Therefore, the memory cell strings MSS each including a ground selection transistor GST, a string selection transistor SST, and memory cell transistors MC1 to MCn connected in series to each other between the ground selection transistor GST and the string selection transistor SST may be provided. In some embodiments, at least one of the gate electrodes 230 may function as a dummy word line, but embodiments are not limited thereto.

Stack isolation layers WLI may be arranged in stack isolation openings WLH extending in the vertical direction Z through the gate electrodes 230 and the mold insulating layers 232. The stack isolation insulating layers WLI may have upper surfaces disposed at a higher vertical (Z=direction) level than the uppermost gate electrode 230 and may protrude upward from the uppermost gate electrode 230. In some embodiments, gate electrodes 230 disposed between a pair of stack isolation openings WLH may form a block.

The channel structures 240 may be respectively disposed in channel holes 240H that extend vertically (Z-direction) through the gate electrodes 230 and the mold insulating layers 232. The channel structures 240 may each include a gate insulating layer 242, a channel layer 244, a buried insulating layer 246, and a drain region 248. The gate insulating layer 242, the channel layer 244, and the buried insulating layer 246 may be sequentially disposed on an inner wall of the channel hole 240H.

The channel structures 240 may each include a first end 240x disposed adjacent to the peripheral circuit structure PS and a second end 240y that is opposite the first end 240x. In example embodiments, the channel structures 240 may each have a sloped side wall such that the width of the first end 240x may be greater than the width of the second end 240y. The horizontal cross-sectional areas of the channel structures 240 and the channel holes 240H may be less than the horizontal cross-sectional areas of contact plug holes CH, but embodiments are not limited thereto.

The drain regions 248, electrically connected to the channel layers 244, may be disposed on the first ends 240x of the channel structures 240. The drain regions 248 may be connected to bit line contacts BLC, and the channel layers 244 may be electrically connected to bit lines BL through the drain regions 248 and the bit line contacts BLC. At the second ends 240y of the channel structures 240, upper surfaces of the channel layers 244 may not be covered by the gate insulating layers 242, i.e., the upper surfaces of the channel layers 244 may be free of the gate insulating layers 242, and the common source layer 210 may be connected to the upper surfaces of the channel layers 244.

In some embodiments, each of the gate insulating layers 242 may include a tunneling dielectric layer, a charge storage layer, and a blocking dielectric layer that are sequentially provided on an outer side wall of the channel layer 244. The charge storage layer is a region in which electrons passing through the tunneling dielectric layer from the channel layer 244 may be stored. The charge storage layer may include silicon nitride, boron nitride, silicon boron nitride, and/or polysilicon doped with a dopant.

In some embodiments, the charge storage layer may include a ferroelectric dielectric material. In this case, the charge storage layer may include a metal oxide having ferroelectric properties. For example, the charge storage layer may include a ferroelectric material capable of storing data through hysteresis behavior caused by a voltage applied to the charge storage layer. In example embodiments, the charge storage layer may include at least one material selected from the group consisting of hafnium oxide, zirconium oxide, and/or hafnium zirconium oxide.

An etch stop layer 222 may be disposed on the uppermost gate electrode 230, and the etch stop layer 222 may include polysilicon. In some embodiments, the etch stop layer 222 may be omitted.

The common source layer 210 may be conformally formed on the etch stop layer 222. The common source layer 210 may be connected to the second ends 240y of the channel structures 240 and may be on and at least partially cover upper surfaces of the stack isolation insulating layers WLI. From a planar perspective, the common source layer 210 may be disposed in the entire area of the cell region MCR.

In example embodiments, the common source layer 210 may include at least one material selected from the group consisting of silicon (Si), germanium (Ge), silicon germanium (SiGe), gallium arsenide (GaAs), indium gallium arsenide (InGaAs), and/or aluminum gallium arsenide (AlGaAs). In addition, the common source layer 210 may include a semiconductor doped with an n-type dopant. In addition, the common source layer 210 may have a crystalline structure including at least one material selected from the group consisting of a single-crystal structure, an amorphous structure, and/or a polycrystalline structure. In some embodiments, the common source layer 210 may include polysilicon doped with an n-type dopant.

Connection vias 252, connection wiring layers 254, and an interlayer insulating layer 256 at least partially surrounding the connection vias 252 and the connection wiring layers 254 may be disposed between a stack cover insulating layer 234 and the peripheral circuit structure PS. The connection vias 252 and the connection wiring layers 254 may be configured as multiple layers disposed at different vertical levels and may electrically connect the bit lines BL, the contact plugs CP, and the peripheral plugs PCP to the peripheral circuit structure PS through the connection pads 260.

The gate electrodes 230 may extend horizontally, e.g., X-direction as shown in FIG. 5 in the cell region MCR and the connection region CON. The gate electrodes 230 may vertically (X-direction) overlap each other in the connection region CON. For example, the gate electrodes 230 disposed at different vertical (Z-direction) levels in the connection region CON may have the same horizontal width.

In the connection region CON, the contact plugs CP may extend in the vertical direction Z through the stack cover insulating layer 234, the mold insulating layers 232, and the gate electrodes 230. The contact plugs CP may have different heights in the vertical direction Z. In example embodiments, each of the contact plugs CP may have a first end CPx and a second end CPy, and the first ends CPx of the contact plugs CP may be at the same vertical level (Z-direction). In addition, the first ends CPx of the contact plugs CP may be at the same vertical level (Z-direction) as an upper surface of the stack cover insulating layer 234. The second ends CPy of the contact plugs CP may be at different vertical levels (Z-direction). For example, each of the second ends CPy of the contact plugs CP may be connected to a corresponding gate electrode 230.

In example embodiments, bottom surfaces of the contact plugs CP may be respectively in contact with corresponding gate electrodes 230, allowing each of the contact plugs CP to be electrically connected to a corresponding gate electrode 230. In example embodiments, side walls of the contact plugs CP may be at least partially surrounded by insulating spacers 236, respectively. For example, each of the insulating spacers 236 may be disposed between a contact plug CP and a gate electrode 230 corresponding to the contact plug CP.

In example embodiments, the bottom surface of a contact plug CP may be electrically connected to a corresponding gate electrode 230, and the side wall of the contact plug CP may not be electrically connected to gate electrodes 230 disposed at lower vertical levels (Z-direction) than the corresponding gate electrode 230. An insulating spacer 236 may be arranged between the side wall of the contact plug CP and the gate electrodes 230 disposed at lower vertical levels (Z-direction) than the corresponding gate electrode 230, thereby insulating the side wall of the contact plug CP from the gate electrodes 230 disposed at lower vertical levels (Z-direction) than the corresponding gate electrode 230. Here, the gate electrodes 230 disposed at lower vertical levels (Z-direction) than the corresponding gate electrode 230 may refer to gate electrodes 230 that are closer to the peripheral circuit structure PS than the corresponding gate electrode 230.

In example embodiments, the horizontal width of each of the contact plug holes CH may be constant. Therefore, the horizontal width (X-direction) of each of the contact plugs CP may also be constant. In other embodiments, each of the contact plug holes CH may have a sloped shape such that the horizontal width of the contact plug hole CH may decrease in a direction from the first end CPx of the contact plug CP toward the second end CPy of the contact plug CP. As a result, each of the contact plugs CP may also have a sloped shape such that the horizontal width of the contact plug CP may decrease in a direction from the first end CPx of the contact plug CP toward the second end CPy of the contact plug CP.

In example embodiments, the contact plugs CP may include a metal such as tungsten, nickel, cobalt, and/or tantalum; a metal silicide such as tungsten silicide, nickel silicide, cobalt silicide, and/or tantalum silicide; doped polysilicon; or a combination thereof. In example embodiments, the insulating spacers 236 may include silicon oxide. In some embodiments, the insulating spacers 236 may include silicon oxide containing one of chlorine, fluorine, and bromine in a small amount (for example, 5 atomic percent (at %) or less).

In example embodiments, the insulating spacers 236 may be conformally disposed in the contact plug holes CH. The insulating spacers 236 may have an annular horizontal cross-sectional shape. In addition, the horizontal width (X-direction) of each of the insulating spacers 236 may be constant. However, embodiments are not limited thereto. For example, the insulating spacers 236 may have a sloped shape such that the horizontal widths of the insulating spacers 236 may decrease in a direction from the first ends CPx of the contact plugs CP toward the second ends CPy of the contact plugs CP.

An upper insulating layer 272 may be disposed on the common source layer 210. The upper insulating layer 272 may have an upper surface extending evenly throughout the cell region MCR and the connection region CON. A common source contact 274 may penetrate or extend through the upper insulating layer 272 and may be connected to the common source layer 210, and a rear wiring layer 276 electrically connected to the common source contact 274 may be disposed on the upper insulating layer 272.

A passivation layer 278 on and at least partially covering the rear wiring layer 276 may be disposed on the upper insulating layer 272. The passivation layer 278 may include an opening OP that at least partially exposes an upper surface of the rear wiring layer 276.

Although not shown in FIGS. 3 to 5, dummy channels (not shown) extending in the vertical direction Z through the gate electrodes 230 and the mold insulating layers 232 may be further formed in the connection region CON. The dummy channels may be formed to guarantee or improve structural stability and reduce or prevent the leaning or bending of the gate electrodes 230 during manufacturing processes of the semiconductor device 100.

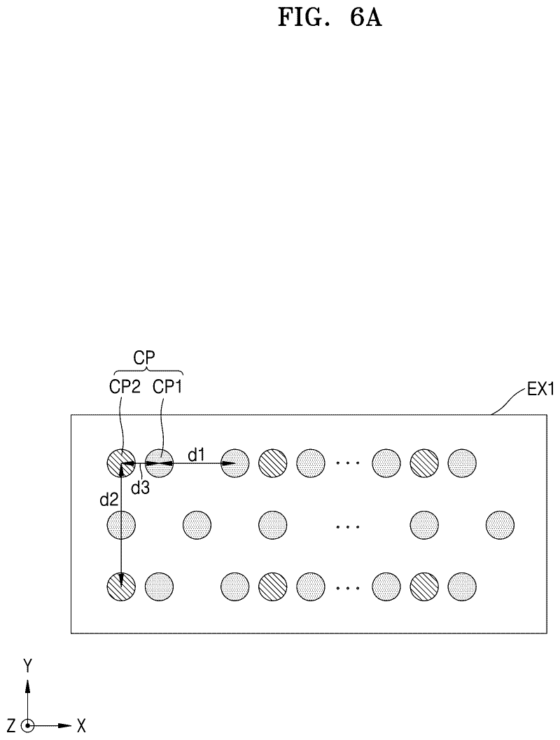

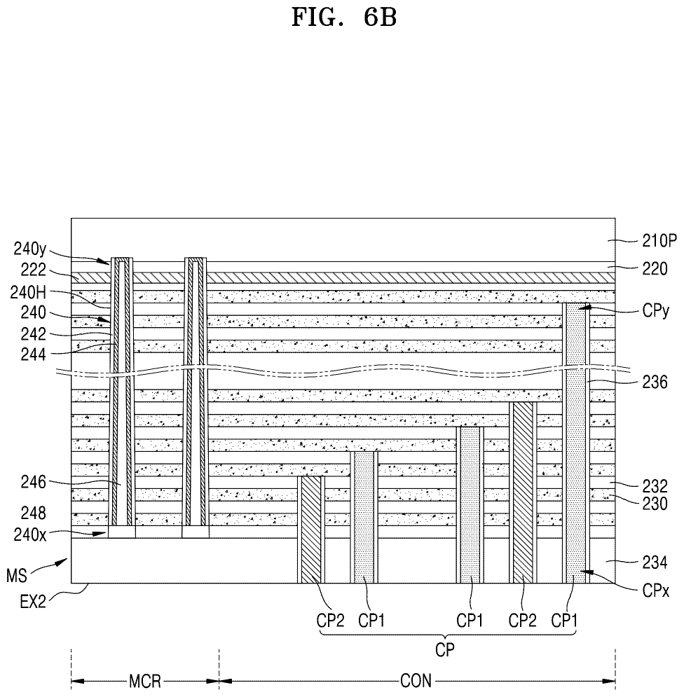

FIG. 6A is an enlarged diagram illustrating a portion EX1 of FIG. 4.

FIG. 6B is an enlarged diagram illustrating a portion EX2 of FIG. 5.

Referring to FIGS. 6A and 6B, the contact plugs CP may include a plurality of first contact plugs CP1 and a plurality of second contact plugs CP2. The bottom surface of each of the first contact plugs CP1 and the second contact plugs CP2 may be electrically connected to a corresponding gate electrode 230.

In example embodiments, the side wall of each of the first contact plugs CP1 and the second contact plugs CP2 may be at least partially surrounded by the insulating spacer 236. While the bottom surface of each of the first contact plugs CP1 and the second contact plugs CP2 are respectively and electrically connected to the corresponding gate electrodes 230, the side wall of each of the contact plugs CP1 and the second contact plugs CP2 may not be electrically connected to gate electrodes 230 disposed at lower vertical levels (Z-direction) than the corresponding gate electrode 230.

In example embodiments, the first contact plugs CP1 and the second contact plugs CP2 may include the same material. For example, the first contact plugs CP1 and the second contact plugs CP2 may include a metal such as tungsten, nickel, cobalt, and/or tantalum; metal silicide such as tungsten silicide, nickel silicide, cobalt silicide, and/or tantalum silicide; doped polysilicon; or a combination thereof. In example embodiments, the insulating spacers 236 may include silicon oxide. In some embodiments, the insulating spacers 236 may include silicon oxide containing one of chlorine, fluorine, and bromine in a small amount (for example, 5 at % or less).

In example embodiments, the first contact plugs CP1 may be arranged apart from each other in a horizontal direction by a first distance d1. For example, the first contact plugs CP1 may be arranged apart from each other in the first horizontal direction X by the first distance d1, but embodiments are not limited thereto. The second contact plugs CP2 may be arranged apart from each other in a horizontal direction by a second distance d2. Here, the second distance d2 may be greater than or equal to the first distance d1.

In example embodiments, the first contact plugs CP1 may each be disposed at the vertices of polygons. For example, the first contact plugs CP1 may be disposed at the vertices and centers of hexagons, forming a honeycomb pattern. In other embodiments, the first contact plugs CP1 may be disposed at the vertices of tetragons.

In example embodiments, each of the second contact plugs CP2 may be disposed among a plurality of first contact plugs CP1. For example, the second contact plugs CP2 may be disposed at the center between two adjacent first contact plugs CP1. In addition, the second contact plugs CP2 may be disposed at the center of gravity of three adjacent first contact plugs CP1. In other embodiments, when the first contact plugs CP1 are disposed at the vertices of polygons, the second contact plugs CP2 may be disposed at the centers of gravity of the polygons.

In example embodiments, the second contact plugs CP2 may be arranged apart from adjacent first contact plugs CP1 by a third distance d3. Here, the third distance d3 may be less than the first distance d1. During a process of forming the contact plug holes CH before forming the contact plugs CP, a minimum separation distance may be required between the contact plug holes CH to reduce or prevent process defects. Here, the minimum separation distance to reduce or prevent defects in the semiconductor device 100 may be the first distance d1. According to example embodiments, the semiconductor device 100 includes contact plugs CP arranged at a distance less than or equal to the minimum separation distance, and thus, the degree of integration of the semiconductor device 100 may increase.

In a semiconductor device of a comparative example, the distance between contact plugs may be greater than or equal to a minimum separation distance to reduce or prevent process defects. However, the semiconductor device 100 of embodiments of the inventive concept includes a plurality of contact plugs CP arranged apart from each other by a distance less than or equal to the minimum separation distance (that is, the first distance d1), and thus, the number of contact plugs CP per unit area may increase in the connection region CON. Thus, the area of the connection region CON may be reduced to increase the degree of integration of the semiconductor device 100. Even when the second contact plugs CP2 are arranged at a third distance d3 less than the first distance d1 from adjacent first contact plugs CP1, the occurrence of process defects in the semiconductor device 100 may be reduced or prevented by separating processes. A method of forming the first contact plugs CP1 and the second contact plugs CP2 is described below.

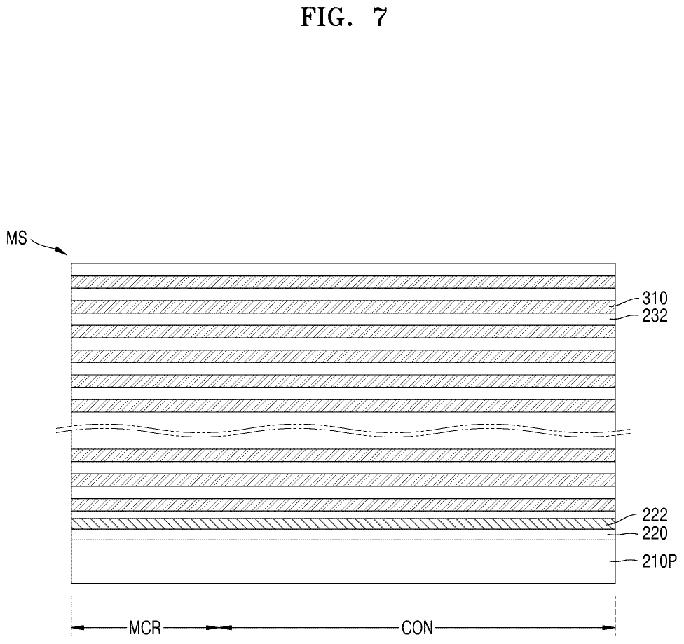

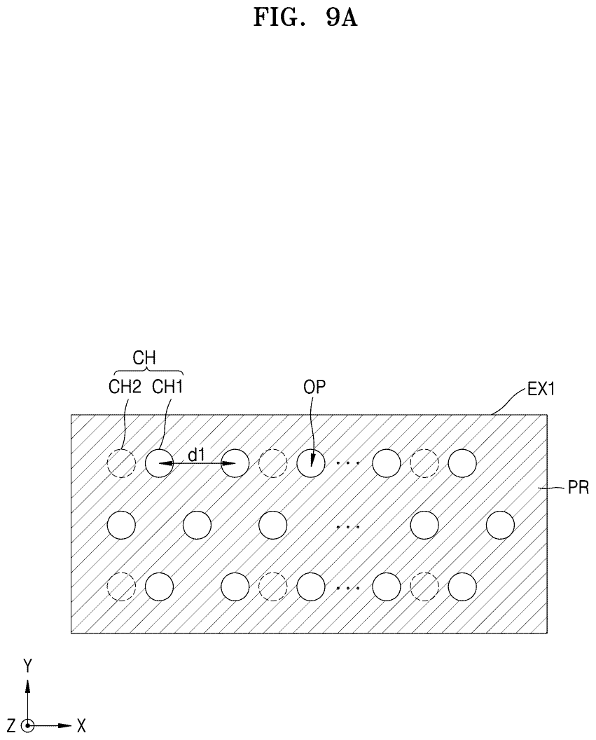

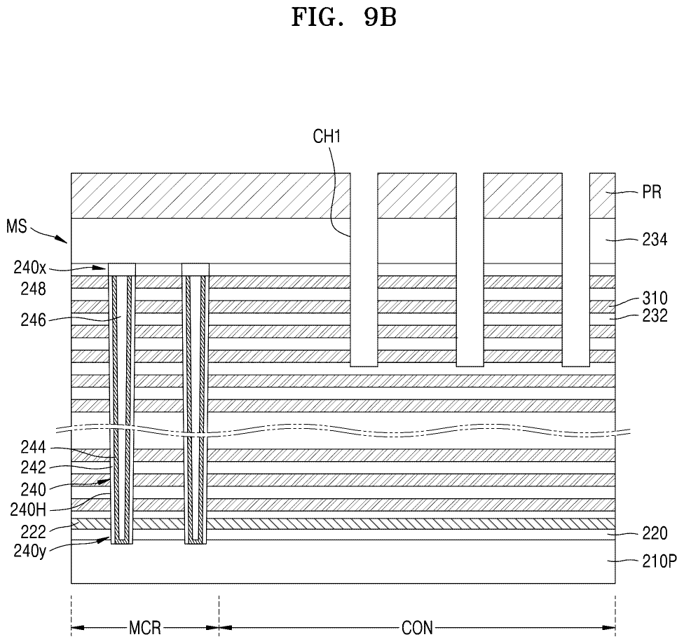

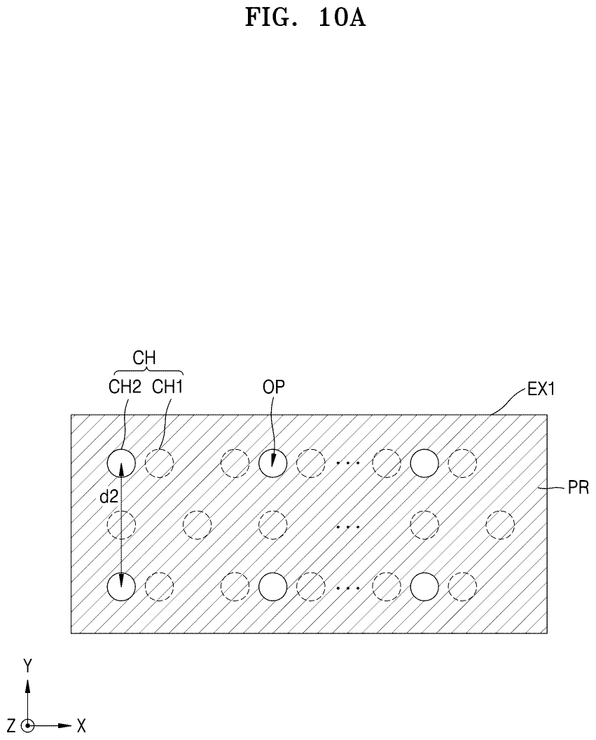

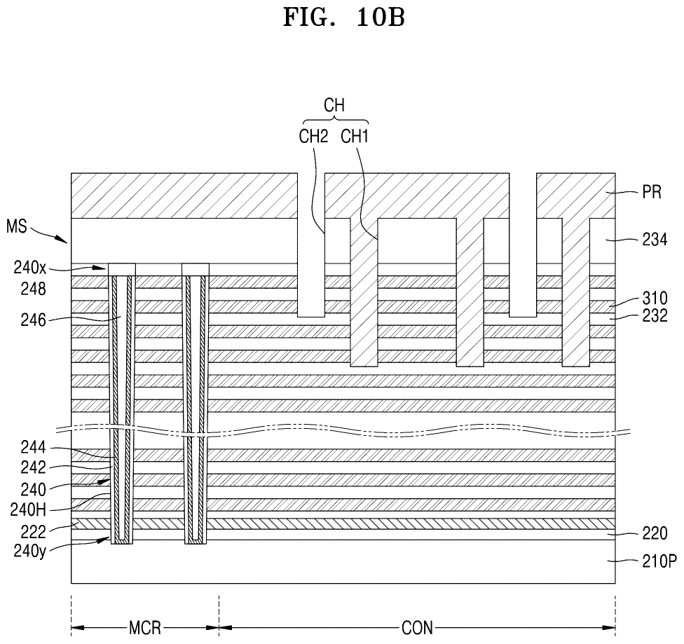

FIGS. 7, 8, 9A, 9B, 10A, 10B, 11A, 11B, and 12 to 14 are diagrams illustrating a method of manufacturing the semiconductor device 100 according to example embodiments. FIGS. 7, 8, 9B, 10B, 11B, 12, 13, and 14 are enlarged cross-sectional diagrams corresponding to the portion EX2 of FIG. 5, and FIGS. 9A, 10A, and 10B are enlarged plan diagrams corresponding to the portion EX1 of FIG. 4.

Referring to FIG. 7, a buffer insulating layer 220 may be formed on a cell substrate 210P, and an etch stop layer 222 may be formed on the buffer insulating layer 220.

In example embodiments, the cell substrate 210P may include at least one material selected from the group consisting of silicon (Si), germanium (Ge), silicon-germanium (SiGe), gallium arsenide (GaAs), indium gallium arsenide (InGaAs), and/or aluminum gallium arsenide (AlGaAs). The buffer insulating layer 220 may include silicon oxide. In example embodiments, the etch stop layer 222 may include polysilicon.

In example embodiments, a mold stack MS may be formed by alternately forming sacrificial layers 310 and mold insulating layers 232 on the etch stop layer 222 in a cell region MCR and a connection region CON. In some embodiments, the sacrificial layers 310 and the mold insulating layers 232 may include materials having an etch selectivity with respect to each other. For example, the sacrificial layers 310 may include silicon nitride, and the mold insulating layers 232 may include silicon oxide.

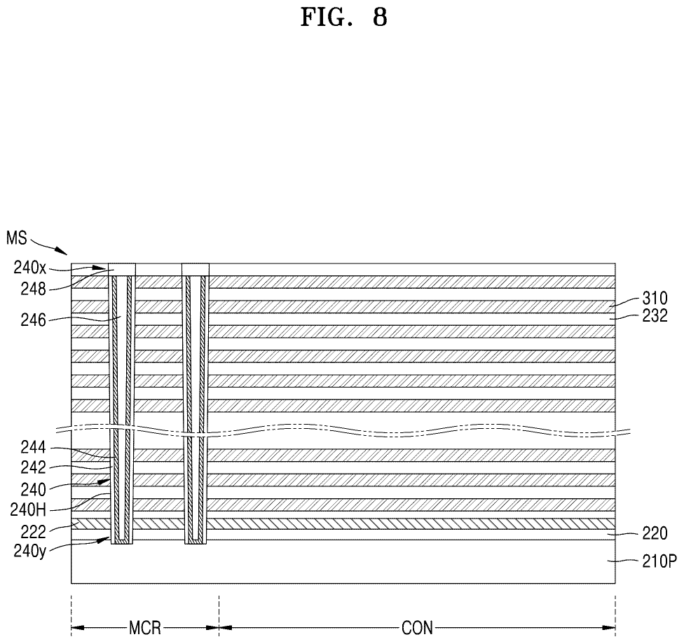

Referring to FIG. 8, channel structures 240 extending through the mold stack MS in a vertical direction Z may be formed in the cell region MCR.

In example embodiments, during a process of forming the channel structures 240, channel holes 240H penetrating or extending through the mold stack MS may be formed in the cell region MCR; a gate insulating layer 242, a channel layer 244, and a buried insulating layer 246 may be sequentially formed on an inner wall of each of the channel holes 240H; and a drain region 248 may be formed at an entrance of each of the channel holes 240H.

In example embodiments, the channel holes 240H may extend through the mold stack MS, the etch stop layer 222, and the buffer insulating layer 220 in the vertical direction Z, and an upper surface of the cell substrate 210P may be exposed at bottom portions of the channel holes 240H.

The channel structures 240 may each have a first end 240x and a second end 240y that is opposite the first end 240x, and the first end 240x may be adjacent to or at the same vertical level (Z-direction) as an upper surface of the mold stack MS. The second end 240y of the channel structure 240 may be in contact with the upper surface of the cell substrate 210P and may be at a lower vertical level (Z-direction) than the upper surface of the cell substrate 210P. In some embodiments, the horizontal width of the first end 240x of the channel structure 240 may be greater than the horizontal width of the second end 240y of the channel structure 240.

Referring to FIGS. 9A, 9B, 10A, 10B, 11A, and 11B, a stack cover insulating layer 234 may be formed on the upper surface of the mold stack MS. The stack cover insulating layer 234 may entirely cover the upper surface of the mold stack MS in the cell region MCR and the connection region CON. The stack cover insulating layer 234 may have flat upper and bottom surfaces extending throughout the cell region MCR and the connection region CON and may have a uniform thickness throughout the cell region MCR and the connection region CON.

In this case, stack isolation openings WLH (refer to FIG. 5) extending in the vertical direction Z through the mold stack MS and the stack cover insulating layer 234 may be formed in the cell region MCR and the connection region CON. The stack isolation openings WLH may extend in a first horizontal direction X (refer to FIG. 4) in the cell region MCR and the connection region CON.

In some embodiments, a dummy channel hole extending in the vertical direction Z through the mold stack MS may be formed in the connection region CON. In some embodiments, a process of forming the dummy channel hole may be performed simultaneously with an etching process for forming the stack isolation openings WLH. In other example embodiments, the process of forming the dummy channel hole may be performed simultaneously with an etching process for forming the channel structures 240.

A plurality of contact plug holes CH extending in the vertical direction Z through portions of the stack cover insulating layer 234 and the mold stack MS may be formed in the connection region CON. In example embodiments, the contact plug holes CH may expose the mold insulating layer 232. A photoresist pattern PR may be formed on the stack cover insulating layer 234 to at least partially cover the mold stack MS and the contact plug holes CH. The photoresist pattern PR may include openings OP corresponding to contact plug holes CH that are to be etched in each process.

In example embodiments, the contact plug holes CH may include a plurality of first contact plug holes CH1 and a plurality of second contact plug holes CH2. The first contact plug holes CH1 may be arranged apart from each other in a horizontal direction by a first distance d1. For example, the first contact plug holes CH1 may be arranged apart from each other in the first horizontal direction X by the first distance d1, but embodiments are not limited thereto. Here, the first distance d1 may refer to a minimum separation distance for reducing or preventing defects in the semiconductor device 100 during processes. For example, the first distance d1 may be 1.4 μm, but embodiments are not limited thereto.

In example embodiments, the second contact plug holes CH2 may be arranged apart from each other in a horizontal direction by a second distance d2. Here, the second distance d2 may be greater than or equal to the first distance d1.

In example embodiments, the second contact plug holes CH2 may be arranged apart from adjacent first contact plug holes CH1 by a third distance d3. Here, the third distance d3 may be less than the first distance d1.

In example embodiments, the first contact plug holes CH1 may be disposed at the vertices of polygons. For example, the first contact plugs CP1 may be disposed at the vertices and centers of hexagons, forming a honeycomb pattern. The second contact plug holes CH2 may be disposed between the first contact plug holes CH1. For example, the second contact plug holes CH2 may each be disposed at the center between two adjacent first contact plug holes CH1.

According to example embodiments, in the method of manufacturing the semiconductor device 100 of embodiments of the inventive concept, an etching process for forming contact plug holes CH arranged at a distance less than the first distance d1 in a horizontal direction may not be performed at once. Among the contact plug holes CH, only contact plug holes CH arranged apart from each other by at least the first distance d1 in a horizontal direction may be selectively formed at the same time.

In example embodiments, referring to FIGS. 9A and 9B, the mold stack MS may be selectively removed to simultaneously form only the first contact plug holes CH1 among the contact plug holes CH. To form the first contact plug holes CH1 arranged apart from each other by the first distance d1 in a horizontal direction among the contact plug holes CH, the photoresist pattern PR may include openings OP corresponding to the first contact plug holes CH1. For example, the openings OP may be arranged apart from each other by the first distance d1 in a horizontal direction and may form a honeycomb pattern in which the openings OP are arranged at the vertices and centers of hexagons. At this time, the first contact plug holes CH1 may be formed after the second contact plug holes CH2 are formed, and in this case, the second contact plug holes CH2 may be at least partially covered by the photoresist pattern PR.

In example embodiments, referring to FIGS. 10A and 10B, the mold stack MS may be selectively removed to simultaneously form only the second contact plug holes CH2 among the contact plug holes CH. To form the second contact plug holes CH2 arranged apart from each other by the second distance d2 in a horizontal direction among the contact plug holes CH, a photoresist pattern PR may include openings OP corresponding to the second contact plug holes CH2. For example, the openings OP may be arranged apart from each other by the second distance d2 in a horizontal direction and may each be at the center between two adjacent first contact plug holes CH1. In this case, the first contact plug holes CH1 may be at least partially covered by the photoresist pattern PR.

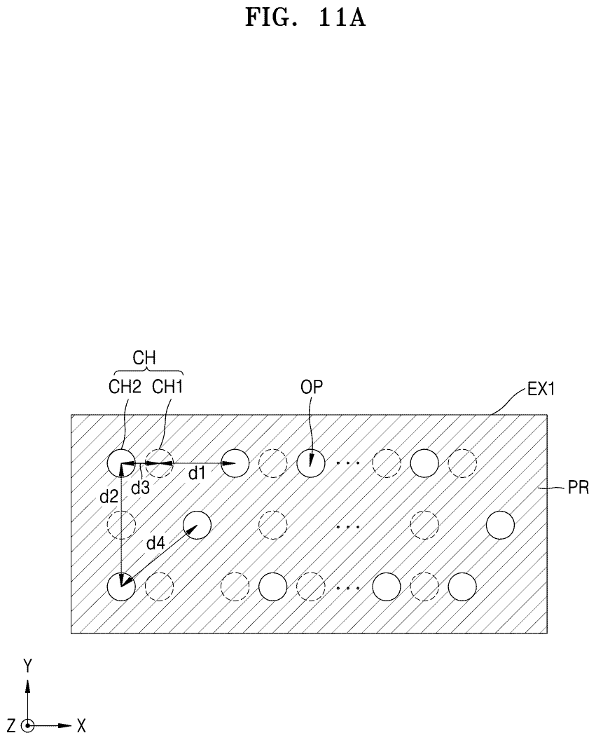

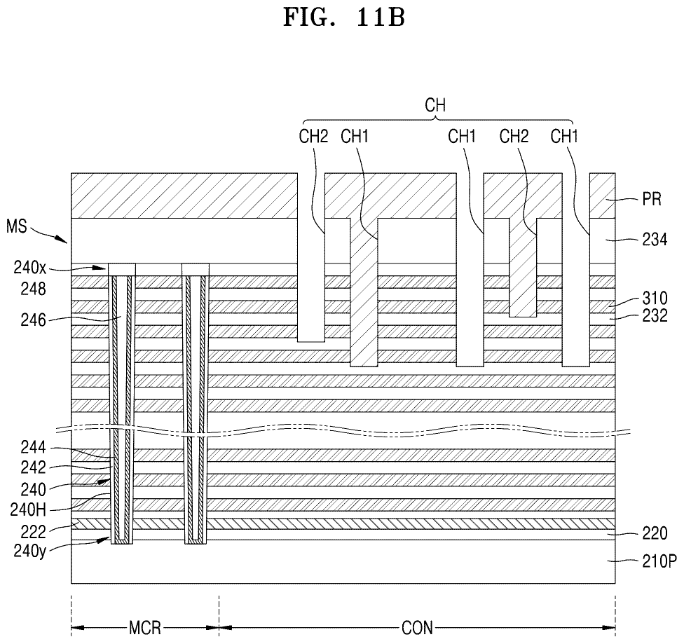

In example embodiments, referring to FIGS. 11A and 11B, the mold stack MS may be selectively removed to simultaneously form first contact plug holes CH1 selected from the first contact plug holes CH1 and second contact plug holes CH2 selected from the second contact plug holes CH2. In this case, the selected first contact plug holes CH1 and the selected second contact plug holes CH2 may be arranged apart from each other by at least the first distance d1 in horizontal directions. For example, when arbitrary first contact plug holes CH1 are formed by etching, second contact plug holes CH2 arranged apart from the arbitrary first contact plug holes CH1 by a fourth distance d4 may be formed simultaneously with the arbitrary first contact plug holes CH1 by etching.

In example embodiments, among the contact plug holes CH, contact plug holes CH arranged apart from each other by at least the first distance d1 in a horizontal direction may be simultaneously formed by etching. First contact plug holes CH1 and second contact plug holes CH2 that are to be simultaneously formed by etching may be arbitrarily selected as long as the first contact plug holes CH1 and the second contact plug holes CH2 are arranged apart from each other by at least the first distance d1. In other words, first contact plug holes CH1 and second contact plug holes CH2 that are simultaneously formed by etching may be arbitrarily arranged. For example, the selected first contact plug holes CH1 may be arranged apart from each other by at least the first distance d1 in a horizontal direction. The selected second contact plug holes CH2 may also be arranged apart from each other by at least the first distance d1 in a horizontal direction. The selected first contact plug holes CH1 and the selected second contact plug holes CH2 may be arranged apart from each other by at least the first distance d1 in a horizontal direction.

However, when the arbitrary first contact plug holes CH1 are formed by etching, second contact plug holes CH2 arranged apart from the arbitrary first contact plug holes CH1 by a distance less than the first distance d1 may not be formed simultaneously with the arbitrary first contact plug holes CH1. For example, when the arbitrary first contact plug holes CH1 are formed by etching, second contact plug holes CH2 arranged apart from the arbitrary first contact plug holes CH1 by the third distance d3 may not be formed simultaneously with the arbitrary first contact plug holes CH1.

To form the selected first contact plug holes CH1 and the selected second contact plug holes CH2 that are arranged apart from each other by at least the first distance d1 among the contact plug holes CH, a photoresist pattern PR may include openings OP corresponding to the selected first contact plug holes CH1 and the selected second contact plug holes CH2. For example, the openings OP may be arbitrarily arranged apart from each other by at least the first distance d1 in a horizontal direction. In this case, unselected first contact plug holes CH1 and unselected second contact plug holes CH2 may be at least partially covered by the photoresist pattern PR.

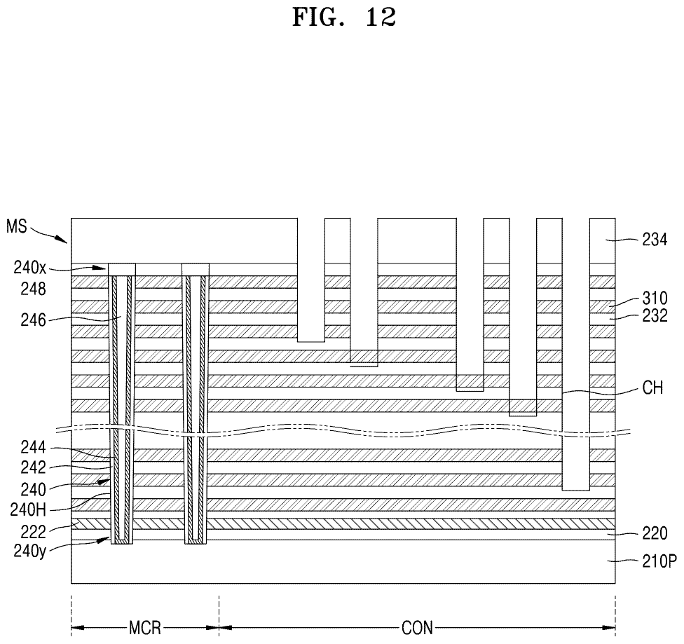

Referring to FIG. 12, the contact plug holes CH may extend vertically (Z-direction) owing to repetition of the process of etching the mold stack MS using a photoresist pattern PR. The processes shown in FIGS. 9A to 11B may be repeated to extend the contact plug holes CH in the vertical direction Z. The process of forming a photoresist pattern PR and selectively removing the mold stack MS using the photoresist pattern PR to form contact plug holes CH may be repeated. In this case, the process of forming only a plurality of first contact plug holes CH1, the process of forming only a plurality of second contact plug holes CH2, and the process of forming arbitrary first contact plug holes CH1 and arbitrary second contact plug holes CH2 together may proceed in any arbitrary order and may be repeated an arbitrary number of times.

In each process of forming the contact plug holes CH, the mold stack MS may be selectively removed to a preset height to form the contact plug holes CH. The height of the mold stack MS that is removed in the same etching process may be uniform. Each etching process may remove 2\hat{ }n layers (where n refers to an integer greater than or equal to 0) of the mold stack MS to form the contact plug holes CH. Removing 2\hat{ }n layers of the mold stack MS may refer to etching 2\hat{ }n sacrificial layers 310 in the vertical direction Z to form the contact plug holes CH.

For example, referring to FIG. 9B, when the contact plug holes CH are formed by selectively removing the mold stack MS, four (for example, 2\hat{ }2) sacrificial layers 310 may be etched to form a plurality of first contact plug holes CH1. For example, referring to FIG. 10B, when the contact plug holes CH are formed by selectively removing the mold stack MS, two (for example, 2\hat{ }1) sacrificial layers 310 may be etched to form a plurality of second contact plug holes CH2. Referring to FIG. 11B, the contact plug holes CH may be extended by selectively removing the mold stack MS by etching one (for example, 2\hat{ }0) sacrificial layer 310 in arbitrary first contact plug holes CH1 and arbitrary second contact plug holes CH2 based on the results shown in FIGS. 9B and 10B. In this case, the processes of etching 2\hat{ }n sacrificial layers 310 may proceed in any arbitrary order and may be repeated an arbitrary number of times.

The contact plug holes CH may have different heights in the Z-direction. The contact plug holes CH may have different heights such that upper surfaces of mold insulating layers 232 corresponding to the sacrificial layers 310 may be exposed. The upper surfaces of the mold insulating layers 232 exposed through the contact plug holes CH may be at different vertical levels (Z-direction). During the process of forming the contact plug holes CH, portions of the mold insulating layers 232 exposed through the contact plug holes CH may be removed together. Therefore, the mold insulating layers 232 may have a smaller thickness at portions exposed through the contact plug holes CH than at the other portions.

Thereafter, the remaining photoresist pattern PR may be removed. As the photoresist pattern PR is removed, the mold stack MS and the stack cover insulating layer 234 may be exposed.

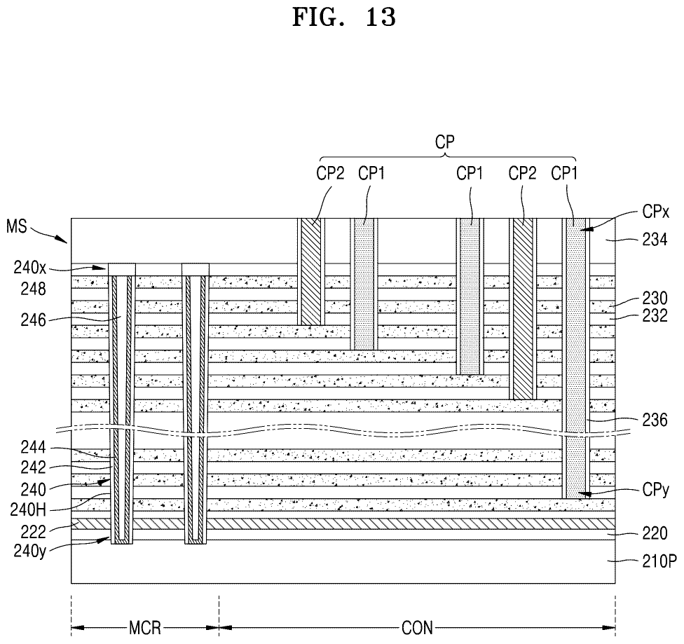

Referring to FIG. 13, insulating spacers 236 on and at least partially covering the contact plug holes CH may be formed. The insulating spacers 236 may be formed to be on and at least partially cover the contact plug holes CH. In example embodiments, the insulating spacers 236 may conformally at least partially cover an exposed upper surface and an exposed side wall of the mold stack MS.

Thereafter, the sacrificial layers 310 (refer to FIG. 12) may be removed, and gate electrodes 230 may be formed using a metal material in spaces from which the sacrificial layers 310 are removed. The vertical thicknesses of the gate electrodes 230 may be substantially the same as the vertical thicknesses of the sacrificial layers 310. As the sacrificial layers 310 are replaced with the gate electrodes 230, the gate electrodes 230 may extend horizontally (X-direction) in the cell region MCR and the connection region CON. In the connection region CON, the gate electrodes 230 may vertically (Z-direction) overlap each other. For example, in the connection region CON, the gate electrodes 230 may be disposed at different vertical levels (Z-direction) and may have the same width in a horizontal direction.

Thereafter, an etch-back process may be performed on bottom portions of the contact plug holes CH to remove portions of lowermost portions of the insulating spacers 236 disposed in the bottom portions of the contact plug holes CH, exposing upper surfaces of the gate electrodes 230.

For example, as a result of the etch-back process, the lower most portions of the insulating spacers 236 and portions of the mold insulating layers 232 that at least partially cover the upper surfaces of the gate electrodes 230 may be removed, and thus, the upper surfaces of the gate electrodes 230 may be exposed.

Thereafter, a plurality of contact plugs CP may be formed inside the contact plug holes CH. Side surfaces of the contact plugs CP may be in contact with side walls of the insulating spacers 236.

In example embodiments, each of the contact plugs CP may have a first end CPx and a second end CPy. The first ends CPx of the contact plugs CP may be disposed at the same vertical level (Z-direction) as an upper surface of the stack cover insulating layer 234, and the second ends CPy of the contact plugs CP may be respectively disposed on corresponding gate electrodes 230.

In example embodiments, bottom surfaces of the contact plugs CP may be respectively in contact with the corresponding gate electrodes 230, and thus, each of the contact plugs CP may be electrically connected to a corresponding gate electrodes 230.

For example, the bottom surface of one contact plug CP may be electrically connected to a corresponding gate electrode 230, and the side wall of the contact plug CP may not be electrically connected to gate electrodes 230 disposed at higher vertical levels (Z-direction) than the corresponding gate electrode 230. An insulating spacer 236 may be disposed between the side wall of the contact plug CP and the gate electrodes 230 disposed at higher vertical levels (Z-direction) than the corresponding gate electrode 230, and thus, the side wall of the contact plug CP may be insulated from the gate electrodes 230 disposed at higher vertical levels (Z-direction) than the corresponding gate electrode 230.

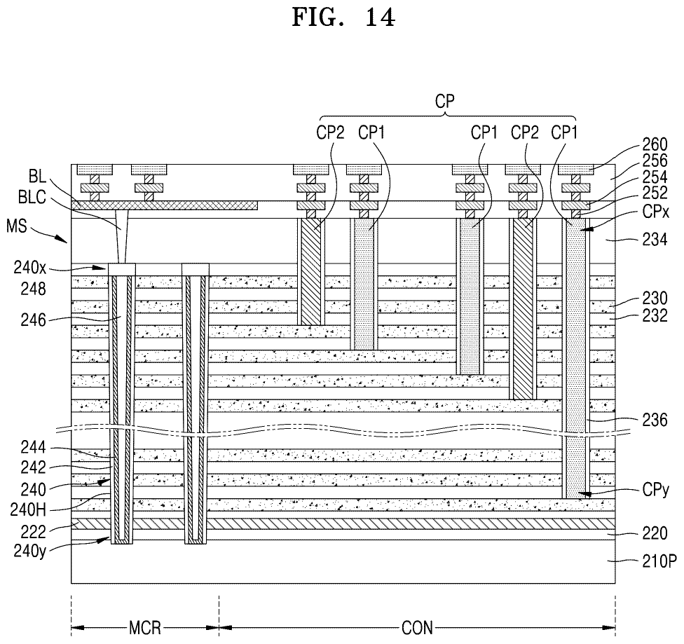

Referring to FIG. 14, bit line contacts BLC and bit lines BL that are electrically connected to the channel structures 240 may be formed. Connection vias 252, connection wiring layers 254, and an interlayer insulating layer 256 that are electrically connected to the bit lines BL and the contact plugs CP may be formed. Connection pads 260 may be formed on an upper surface of the interlayer insulating layer 256.

Referring back to FIG. 5, a peripheral circuit structure PS may be prepared. Peripheral circuit transistors 120TR may be formed on a substrate 110 in which active regions AC are defined by a device isolation layer 112, a plurality of peripheral circuit contacts 132 and a plurality of peripheral circuit wiring layers 134 electrically connected to the peripheral circuit transistors 120TR and the substrate 110 may be formed above the substrate 110, and an interlayer insulating layer 130 may be formed on the substrate 110 to be on and at least partially cover the peripheral circuit transistors 120TR, the peripheral circuit contacts 132, and the peripheral circuit wiring layers 134. Connection pads 260 may be formed on the upper surface of the interlayer insulating layer 130.

Thereafter, the peripheral circuit structure PS may be attached to a cell structure CS. The peripheral circuit structure PS and the cell structure CS may be attached to each other through the connection pads 260 and the interlayer insulating layers 130 and 256 by a metal-oxide hybrid bonding method. However, embodiments are not limited thereto. Thereafter, the peripheral circuit structure PS and that cell structure CS that are attached to each other may be flipped such that the substrate 110 faces upward.

Thereafter, the cell substrate 210P (refer to FIG. 14) may be removed. The cell substrate 210P may be removed by a grinding process and a subsequent etching process, thereby exposing the buffer insulating layer 220 (refer to FIG. 14). The buffer insulating layer 220 may also be removed to expose an upper surface of the etch stop layer 222. As the buffer insulating layer 220 is removed, the second ends 240y of the channel structures 240 may protrude from the upper surface of the etch stop layer 222. As the cell substrate 210P and the buffer insulating layer 220 are removed, upper sides of stack isolation insulating layers WLI may also be exposed and protrude upward from the etch stop layer 222.

Thereafter, portions of the gate insulating layers 242, which are exposed on the second ends 240y of the channel structures 240, may be removed to expose upper surfaces of the channel layers 244. In some embodiments, upper surfaces of the gate insulating layers 242 may be positioned on the same plane (Z-direction) as the upper surfaces of the channel layers 244.

In other example embodiments, during the process of removing the gate insulating layers 242, the gate insulating layers 242 may be removed until the upper surface of the etch stop layer 222 is exposed. In some embodiments, upper sides of the gate insulating layers 242 may be removed such that the gate insulating layers 242 may be lower than the upper surfaces of the channel layers 244 (Z-direction) to expose the upper surfaces and side wall portions of the channel layers 244.

Thereafter, a common source layer 210 may be formed in the cell region MCR, the connection region CON, and a peripheral circuit connection region PRC (refer to FIG. 4). The common source layer 210 may be formed using polysilicon. For example, the common source layer 210 may be formed using polysilicon doped with an n-type dopant. In the cell region MCR, the common source layer 210 may be conformally formed on the exposed upper surface of the etch stop layer 222 and the exposed upper surfaces of the channel layers 244. In this case, portions of the common source layer 210 and the etch stop layer 222 that are in the connection region CON and the peripheral circuit connection region PRC may be removed.

Thereafter, an upper insulating layer 272 may be formed on the common source layer 210 and an uppermost mold insulating layer 232 in the cell region MCR, the connection region CON, and the peripheral circuit connection region PRC.

Thereafter, a mask pattern may be formed on the upper insulating layer 272, and a portion of the upper insulating layer 272 may be removed using the mask pattern as an etching mask to form a rear contact hole. A common source contact 274 may be formed in the rear contact hole, and a rear wiring layer 276 electrically connected to the common source contact 274 may be formed on the upper insulating layer 272.

Thereafter, a passivation layer 278 at least partially covering the rear wiring layer 276 may be formed on the upper insulating layer 272, and an opening OP may be formed in the passivation layer 278 to expose an upper surface of the rear wiring layer 276. The manufacture of the semiconductor device 100 may be completed through the processes described above.

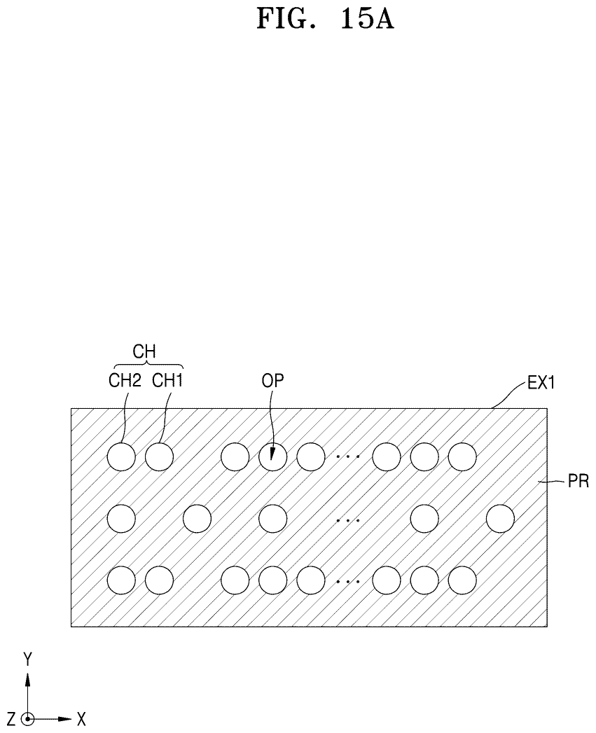

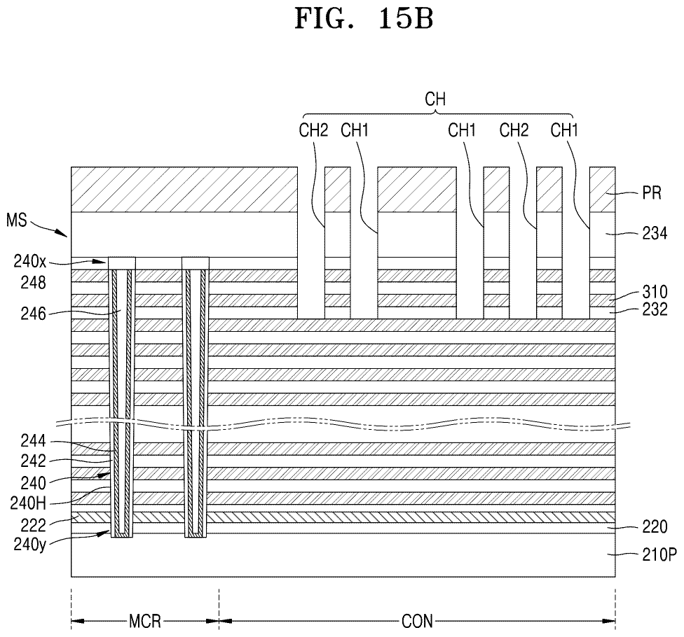

FIG. 15A is an enlarged diagram corresponding to the portion EX1 of FIG. 4, illustrating a method of manufacturing a semiconductor device according to example embodiments.

FIG. 15B is an enlarged cross-sectional diagram corresponding to the portion EX2 of FIG. 5, illustrating a method of manufacturing a semiconductor device according to example embodiments.

FIGS. 15A and 15B illustrate a process of forming a plurality of contact plug holes CH extending in a vertical direction Z by removing portions of a mold stack MS. Descriptions of the same portions as those described with reference to FIGS. 9A to 12 may be omitted.

Referring to FIGS. 15A and 15B, the contact plug holes CH may include a plurality of first contact plug holes CH1 and a plurality of second contact plug holes CH2. The first contact plug holes CH1 may be arranged apart from each other in a horizontal direction by a first distance d1. The second contact plug holes CH2 may be arranged apart from each other in a horizontal direction by a second distance d2. Here, the second distance d2 may be greater than or equal to the first distance d1. The second contact plug holes CH2 may be arranged apart from adjacent first contact plug holes CH1 by a distance less than the first distance d1.

According to example embodiments, in a method of manufacturing the semiconductor device 100 of the present disclosure, contact plug holes CH arranged apart from each other by a distance less than the first distance d1 in a horizontal direction may be simultaneously formed by etching up to a preset height. The first contact plug holes CH1 and the second contact plug holes CH2 may be simultaneously formed up to the preset height. A plurality of first contact plug holes CH1 and a plurality of second contact plug holes CH2 may be simultaneously formed by removing portions of the mold stack MS up to 2\hat{ }n layers (where n refers to an integer greater than or equal to 0). For example, a plurality of first contact plug holes CH1 and a plurality of second contact plug holes CH2 that are arranged apart from each other by a distance less than the first distance d1 may be simultaneously formed up to 1, 2, 4, 8, or 16 layers (for example, n=0, 1, 2, 3, or 4). In this case, n may not be limited to an integer between 0 and 4, and the 2\hat{ }n layers may be set to a height that does not cause process defects in the semiconductor device 100.

After simultaneously forming the first contact plug holes CH1 and the second contact plug holes CH2 up to the preset height, only contact plug holes CH arranged apart from each other by at least a minimum separation distance (for example, the first distance d1) in a horizontal direction may be selectively formed at the same time among the contact plug holes CH. As described above with reference to FIGS. 9A to 12, a process of forming only first contact plug holes CH1, a process of forming only second contact plug holes CH2, and a process of forming arbitrary first contact plug holes CH1 and arbitrary second contact plug holes CH2 together may be repeated to form the contact plug holes CH having different vertical levels (Z-direction).

In example embodiments, when only contact plug holes CH arranged apart from each other by at least the minimum separation distance are selectively formed at the same time among the contact plug holes CH after simultaneously forming the first contact plug holes CH1 and the second contact plug holes CH2 up to the preset height, the minimum separation distance may vary depending on the number of layers etched. In the process of forming the contact plug holes CH by removing 2\hat{ }n layers of the mold stack MS, an arbitrary minimum separation distance may be set depending on the number of layers etched. In this case, the arbitrary minimum separation distance may increase as the number of layers etched increases, but embodiments are not limited thereto.

For example, a plurality of first contact plug holes CH1 and a plurality of second contact plug holes CH2 that are arranged apart from each other by a distance less than the minimum separation distance (for example, the first distance d1) may be simultaneously formed up to 2\hat{ }3 layers. Thereafter, when a plurality of contact plug holes CH are formed by removing 2\hat{ }4 layers of the mold stack MS, only contact plug holes CH arranged apart from each other by at least a first minimum separation distance (for example, the first distance d1) in a horizontal direction may be selectively formed at the same time. When a plurality of contact plug holes CH are formed by removing up to 2\hat{ }5 layers of the mold stack MS, only contact plug holes CH arranged apart from each other by at least a second minimum separation distance in a horizontal direction may be selectively formed at the same time. Here, the second minimum separation distance may be greater than the first minimum separation distance. In addition, when a plurality of contact plug holes CH are formed by removing 2\hat{ }6 layers of the mold stack MS, only contact plug holes CH arranged apart from each other by at least a third minimum separation distance in a horizontal direction may be selectively formed at the same time. Here, the third minimum separation distance may be greater than the second minimum separation distance.

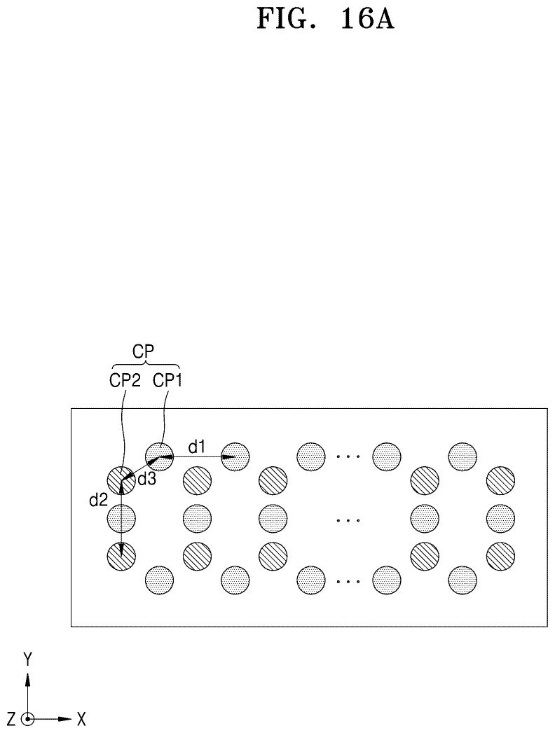

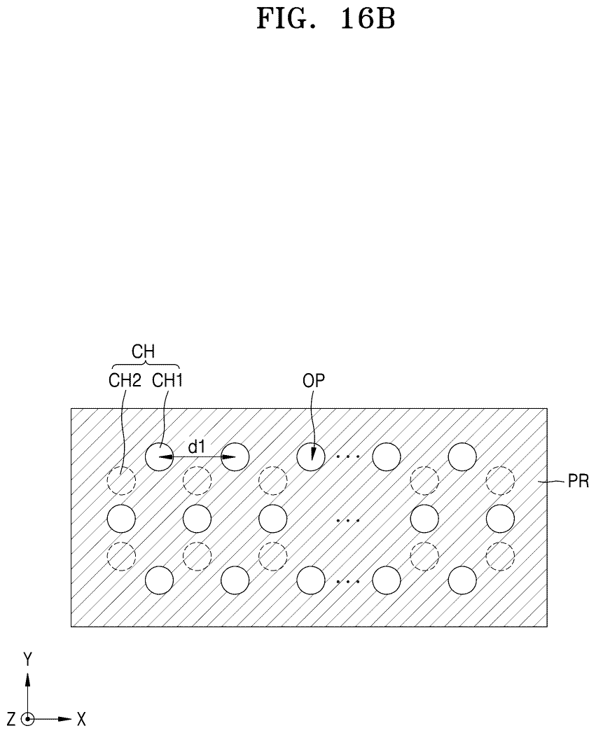

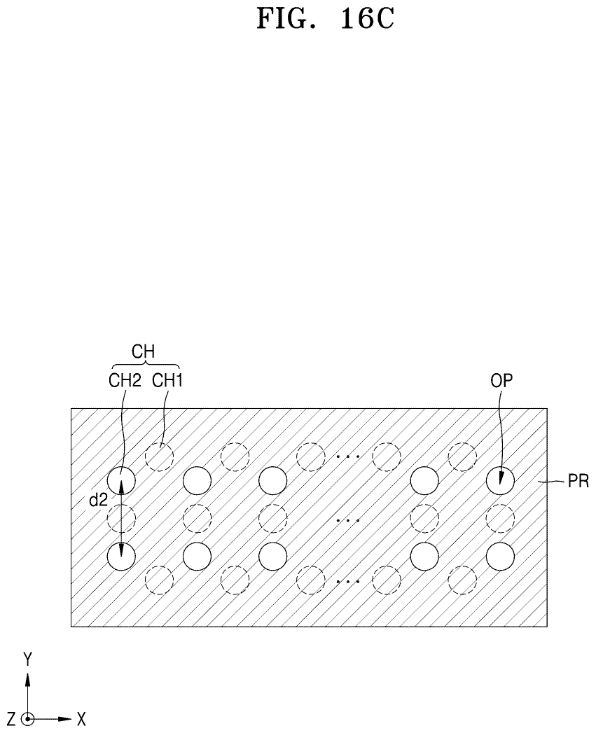

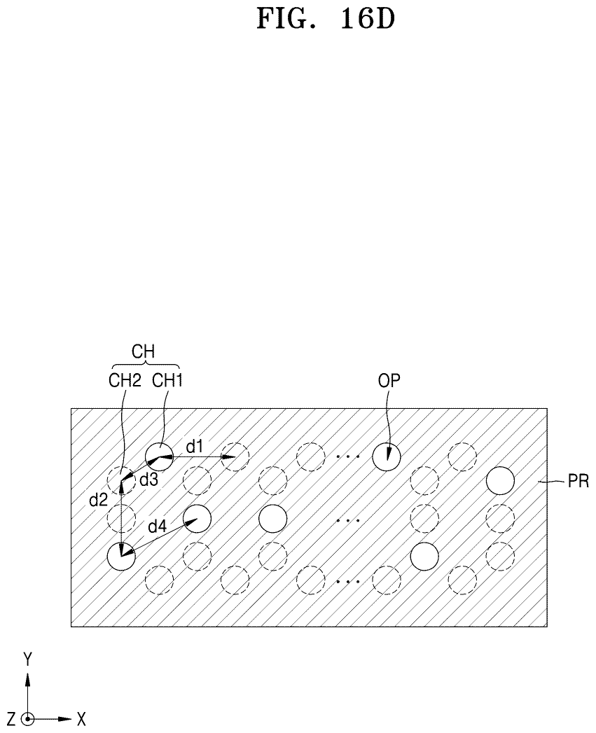

FIG. 16A is an enlarged diagram corresponding to the portion EX1 of FIG. 4, illustrating a layout of contact plugs CP of a semiconductor device according to example embodiments.

Referring to FIG. 16A, the contact plugs CP may include a plurality of first contact plugs CP1 and a plurality of second contact plugs CP2. The first contact plugs CP1 may be arranged apart from each other by a first distance d1 in a horizontal direction. The second contact plugs CP2 may be arranged apart from each other by a second distance d2 in a horizontal direction. Here, the second distance d2 may be greater than or equal to the first distance d1.

In example embodiments, the first contact plugs CP1 may be disposed at the vertices and centers of hexagons, forming a honeycomb pattern. The second contact plugs CP2 may each be disposed between the first contact plugs CP1. For example, each of the second contact plugs CP2 may be disposed at the center of gravity of three adjacent first contact plugs CP1.

In example embodiments, the second contact plugs CP2 may be arranged apart from adjacent first contact plugs CP1 by a third distance d3. In this case, the third distance d3 may be less than the first distance d1. According to embodiments, a process of forming a plurality of contact plug holes CH of the semiconductor device 100 may be divided. Therefore, the semiconductor device 100 may include contact plug holes CH arranged apart from each other by a distance less than or equal to a minimum separation distance, and thus, the degree of integration of the semiconductor device 100 may be improved.

FIGS. 16B to 16D are enlarged plan diagrams corresponding to the portion EX1 of FIG. 4, illustrating a method of manufacturing a semiconductor device according to example embodiments.

FIGS. 16B to 16D illustrate a process of forming a plurality of contact plug holes CH extending in a vertical direction Z by removing portions of a mold stack MS. Descriptions of the same portions as those described with reference to FIGS. 9A to 12 may be omitted.

Referring to FIGS. 16B to 16D, the contact plug holes CH may include a plurality of first contact plug holes CH1 and a plurality of second contact plug holes CH2. The first contact plug holes CH1 may be arranged apart from each other by a first distance d1 in a horizontal direction. Here, the first distance d1 may refer to a minimum separation distance required to prevent defects in the semiconductor device 100 during processes.

In example embodiments, the second contact plug holes CH2 may be arranged apart from each other by a second distance d2 in a horizontal direction. Here, the second distance d2 may be greater than or equal to the first distance d1. In addition, the second contact plug holes CH2 may be arranged apart from adjacent first contact plug holes CH1 by a third distance d3. Here, the third distance d3 may be less than the first distance d1.

In example embodiments, the first contact plug holes CH1 may be disposed at the vertices and centers of hexagons, forming a honeycomb pattern. The second contact plug holes CH2 may each be disposed between the first contact plug holes CH1. For example, each of the second contact plug holes CH2 may be disposed at the center of gravity of three adjacent first contact plug holes CH1.

In example embodiments, in a method of manufacturing the semiconductor device 100 of the present disclosure, contact plug holes CH arranged at a distance less than the first distance d1 in a horizontal direction may not be simultaneously formed by etching. Among the contact plug holes CH, contact plug holes CH arranged apart from each other by at least the first distance d1 in a horizontal direction may be selectively formed at the same time by etching.

Referring to FIG. 16B, in example embodiments, only the first contact plug holes CH1 may be simultaneously formed among the contact plug holes CH. A photoresist pattern PR for forming the first contact plug holes CH1 arranged apart from each other by the first distance d1 in a horizontal direction may include openings OP corresponding to the first contact plug holes CH1. For example, the openings OP may be arranged apart from each other by the first distance d1 in a horizontal direction, forming a honeycomb pattern in which the openings OP are disposed at the vertices and centers of hexagons.

Referring to FIG. 16C, in example embodiments, only the second contact plug holes CH2 may be simultaneously formed among the contact plug holes CH. A photoresist pattern PR for forming the second contact plug holes CH2 arranged apart from each other by the second distance d2 in a horizontal direction may include openings OP corresponding to the second contact plug holes CH2. For example, the openings OP may be arranged apart from each other by the second distance d2 in a horizontal direction and may each be disposed at the center of gravity of three adjacent first contact plug holes CH1.

Referring to FIG. 16D, in example embodiments, first contact plug holes CH1 selected from the first contact plug holes CH1 and second contact plug holes CH2 selected from the second contact plug holes CH2 may be simultaneously formed. In this case, the selected first contact plug holes CH1 and the selected second contact plug holes CH2 may be arranged apart from each other by at least the first distance d1 in a horizontal direction. For example, when arbitrary first contact plug holes CH1 are formed by etching, second contact plug holes CH2 arranged apart from the arbitrary first contact plug holes CH1 by a fourth distance d4 may be formed by etching simultaneously with the arbitrary first contact plug holes CH1. First contact plug holes CH1 and second contact plug holes CH2 that are to be simultaneously formed by etching may be arbitrarily selected as long as the first contact plug holes CH1 and the second contact plug holes CH2 are arranged apart from each other by at least the first distance d1. That is, first contact plug holes CH1 and second contact plug holes CH2 that are simultaneously formed by etching may be arbitrary arranged.

However, when arbitrary first contact plug holes CH1 are formed by etching, second contact plug hole CH2 arranged apart from the arbitrary first contact plug hole CH1 by a distance less than the first distance d1 may not be formed simultaneously with the arbitrary first contact plug holes CH1. For example, when the arbitrary first contact plug holes CH1 are formed by etching, second contact plug holes CH2 arranged apart from the arbitrary first contact plug holes CH1 by the third distance d3 may not be formed simultaneously with the arbitrary first contact plug holes CH1.

To form the selected first contact plug holes CH1 and the selected second contact plug holes CH2 that are arranged apart from each other by at least the first distance d1 among the contact plug holes CH, a photoresist pattern PR may include openings OP corresponding to the selected first contact plug holes CH1 and the selected second contact plug holes CH2. For example, the openings OP may be arbitrarily arranged apart from each other by at least the first distance d1 in a horizontal direction.

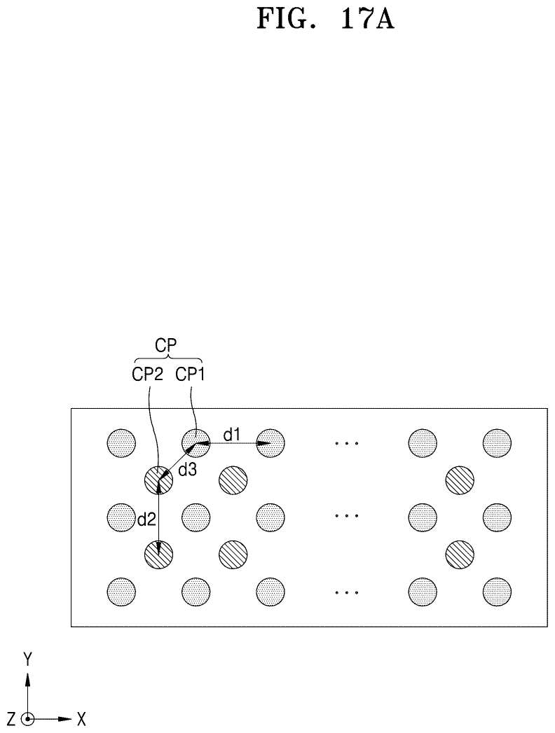

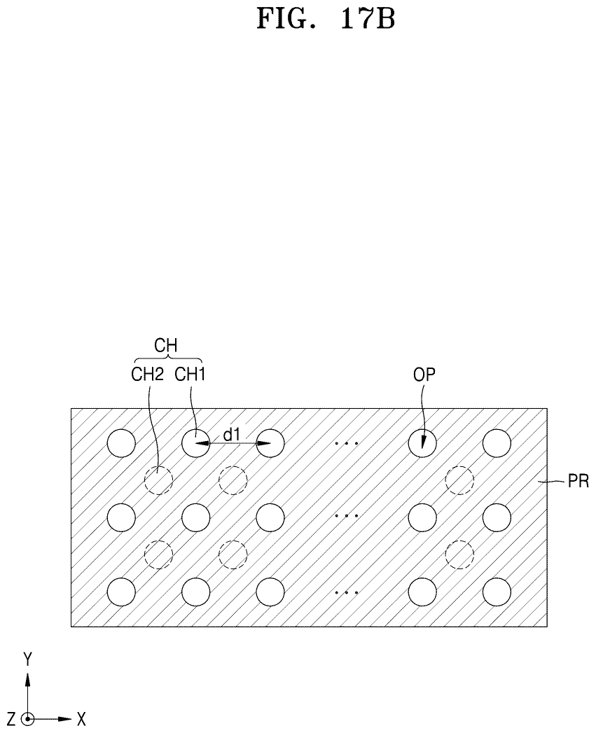

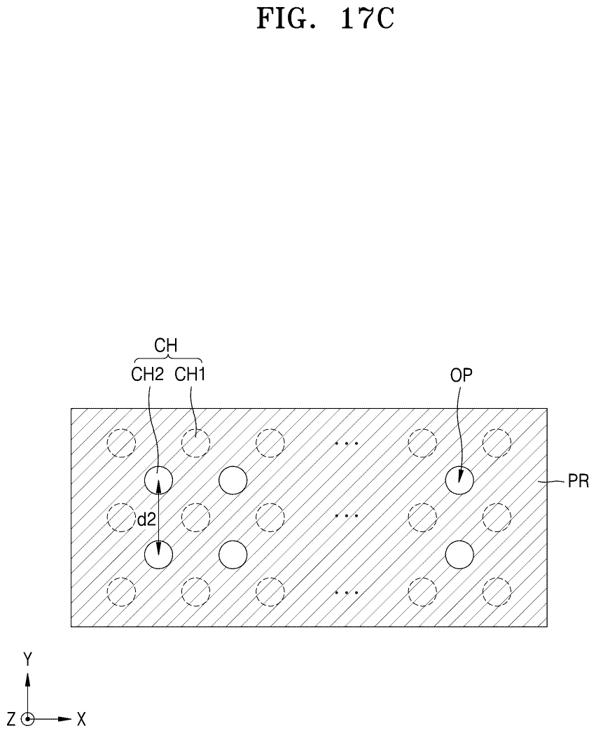

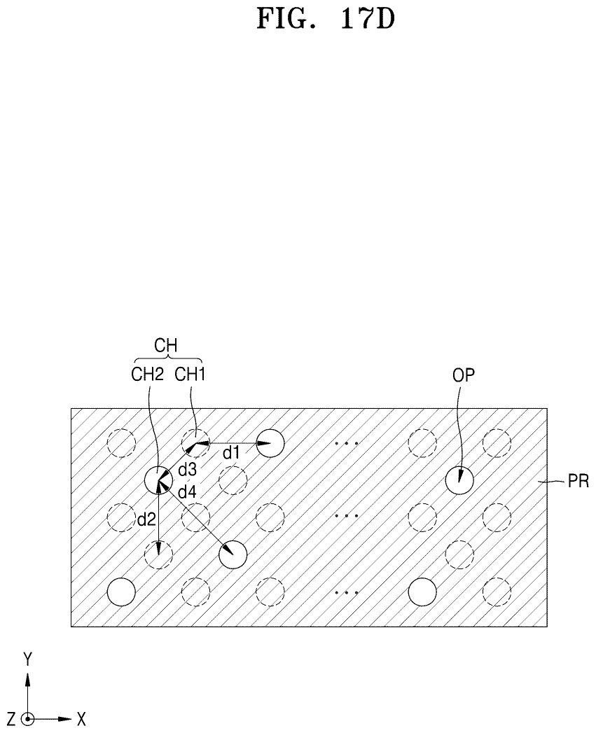

FIG. 17A is an enlarged diagram corresponding to the portion EX1 of FIG. 4, illustrating a layout of contact plugs CP of a semiconductor device according to example embodiments.

Referring to FIG. 17A, the contact plugs CP may include a plurality of first contact plugs CP1 and a plurality of second contact plugs CP2. The first contact plugs CP1 may be arranged apart from each other by a first distance d1 in a horizontal direction. The second contact plugs CP2 may be arranged apart from each other by a second distance d2 in a horizontal direction. Here, the second distance d2 may be greater than or equal to the first distance d1.

In example embodiments, the first contact plugs CP1 may be disposed at the vertices of tetragons. The second contact plugs CP2 may each be disposed between the first contact plugs CP1. For example, the second contact plugs CP2 may be disposed respectively at the centers of gravity of the tetragons.

In example embodiments, the second contact plugs CP2 may be arranged apart from adjacent first contact plugs CP1 by a third distance d3. In this case, the third distance d3 may be less than the first distance d1. According to embodiments, a process of forming a plurality of contact plug holes CH of the semiconductor device 100 may be divided. Therefore, the semiconductor device 100 may include contact plug holes CH arranged apart from each other by a distance less than or equal to a minimum separation distance and, and thus, the degree of integration of the semiconductor device 100 may be improved.

FIGS. 17B to 17D are enlarged plan diagrams corresponding to the portion EX1 of FIG. 4, illustrating a method of manufacturing a semiconductor device according to example embodiments.

FIGS. 17B to 17D illustrate a process of forming a plurality of contact plug holes CH extending in a vertical direction Z by removing portions of a mold stack MS. Descriptions of the same portions as those described with reference to FIGS. 9A to 12 may be omitted.

Referring to FIGS. 17B to 17D, the contact plug holes CH may include a plurality of first contact plug holes CH1 and a plurality of second contact plug holes CH2. The first contact plug holes CH1 may be arranged apart from each other by a first distance d1 in a horizontal direction. Here, the first distance d1 may refer to a minimum separation distance required to prevent defects in the semiconductor device 100 during processes.

In example embodiments, the second contact plug holes CH2 may be arranged apart from each other by a second distance d2 in a horizontal direction. Here, the second distance d2 may be greater than or equal to the first distance d1. In addition, the second contact plug holes CH2 may be arranged apart from adjacent first contact plug holes CH1 by a third distance d3. Here, the third distance d3 may be less than the first distance d1.

In example embodiments, the first contact plug holes CH1 may be disposed at the vertices of tetragons. The second contact plug holes CH2 may each be disposed between the first contact plug holes CH1. For example, the second contact plug holes CH2 may be disposed respectively at the centers of gravity of the tetragons.

In example embodiments, in a method of manufacturing the semiconductor device 100 of the present disclosure, contact plug holes CH arranged at a distance less than the first distance d1 in a horizontal direction may not be simultaneously formed by etching. Among the contact plug holes CH, contact plug holes CH arranged apart from each other by at least the first distance d1 in a horizontal direction may be selectively formed at the same time by etching.

Referring to FIG. 17B, in example embodiments, only the first contact plug holes CH1 may be simultaneously formed among the contact plug holes CH. A photoresist pattern PR for forming the first contact plug holes CH1 arranged apart from each other by the first distance d1 in a horizontal direction may include openings OP corresponding to the first contact plug holes CH1. For example, the openings OP may be arranged apart from each other by the first distance d1 in a horizontal direction, forming a tetragonal pattern in which the openings OP are disposed at the vertices and of tetragons.

Referring to FIG. 17C, in example embodiments, only the second contact plug holes CH2 may be simultaneously formed among the contact plug holes CH. A photoresist pattern PR for forming the second contact plug holes CH2 arranged apart from each other by the second distance d2 in a horizontal direction may include openings OP corresponding to the second contact plug holes CH2. For example, the openings OP may be arranged apart from each other by the second distance d2 in a horizontal direction and may be disposed respectively at the centers of gravity of the tetragons.

Referring to FIG. 17D, in example embodiments, first contact plug holes CH1 selected from the first contact plug holes CH1 and second contact plug holes CH2 selected from the second contact plug holes CH2 may be simultaneously formed. In this case, the selected first contact plug holes CH1 and the selected second contact plug holes CH2 may be arranged apart from each other by at least the first distance d1 in a horizontal direction. For example, when arbitrary first contact plug holes CH1 are formed by etching, second contact plug hole CH2 arranged apart from the arbitrary first contact plug holes CH1 by a fourth distance d4 may be formed by etching simultaneously with the arbitrary first contact plug holes CH1. First contact plug holes CH1 and second contact plug holes CH2 that are to be simultaneously formed by etching may be arbitrarily selected as long as the first contact plug holes CH1 and the second contact plug holes CH2 are arranged apart from each other by at least the first distance d1. That is, first contact plug holes CH1 and second contact plug holes CH2 that are simultaneously formed by etching may be arbitrary arranged.

However, when arbitrary first contact plug holes CH1 are formed by etching, second contact plug hole CH2 arranged apart from the arbitrary first contact plug hole CH1 by a distance less than the first distance d1 may not be formed simultaneously with the arbitrary first contact plug holes CH1. For example, when the arbitrary first contact plug holes CH1 are formed by etching, second contact plug holes CH2 arranged apart from the arbitrary first contact plug holes CH1 by the third distance d3 may not be formed simultaneously with the arbitrary first contact plug holes CH1.

To form the selected first contact plug holes CH1 and the selected second contact plug holes CH2 that are arranged apart from each other by at least the first distance d1 among the contact plug holes CH, a photoresist pattern PR may include openings OP corresponding to the selected first contact plug holes CH1 and the selected second contact plug holes CH2. For example, the openings OP may be arbitrarily arranged apart from each other by at least the first distance d1 in a horizontal direction.

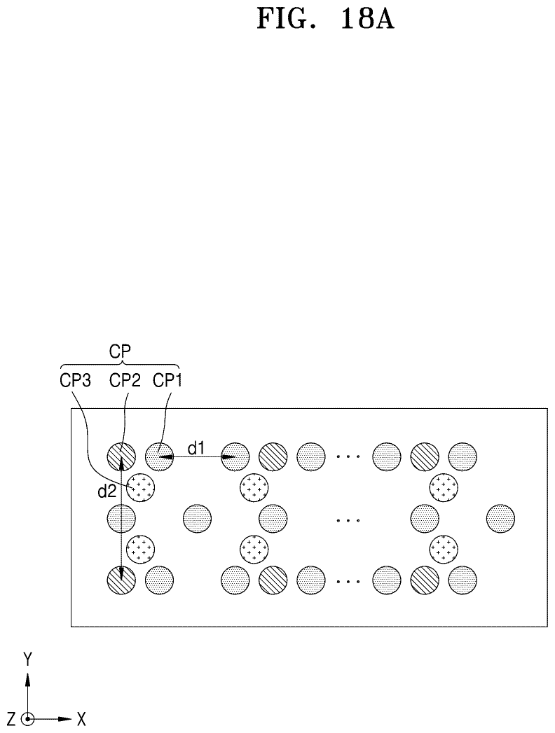

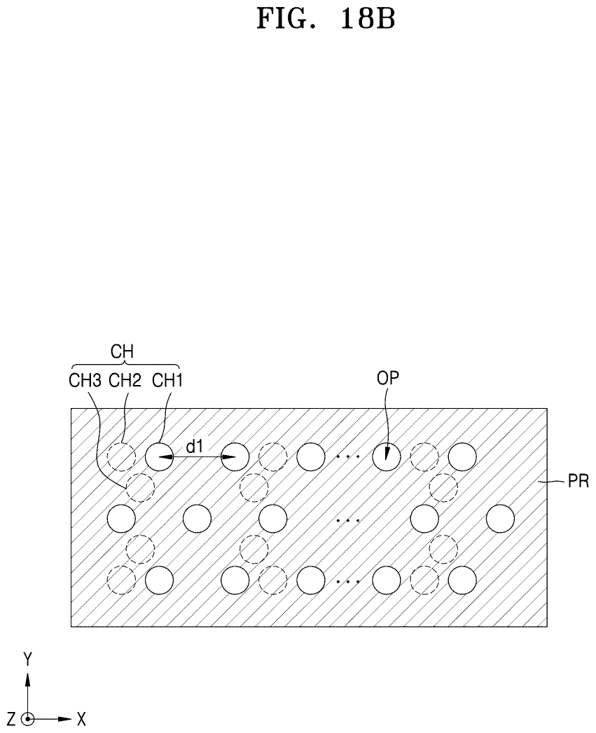

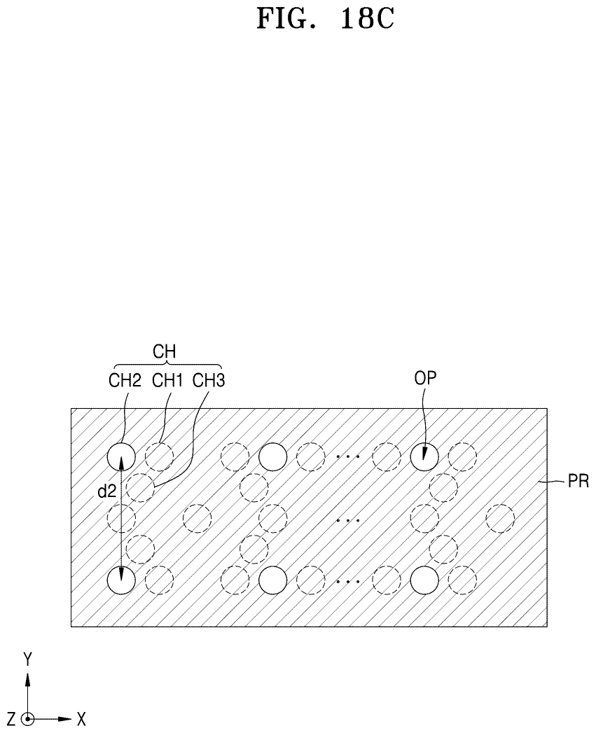

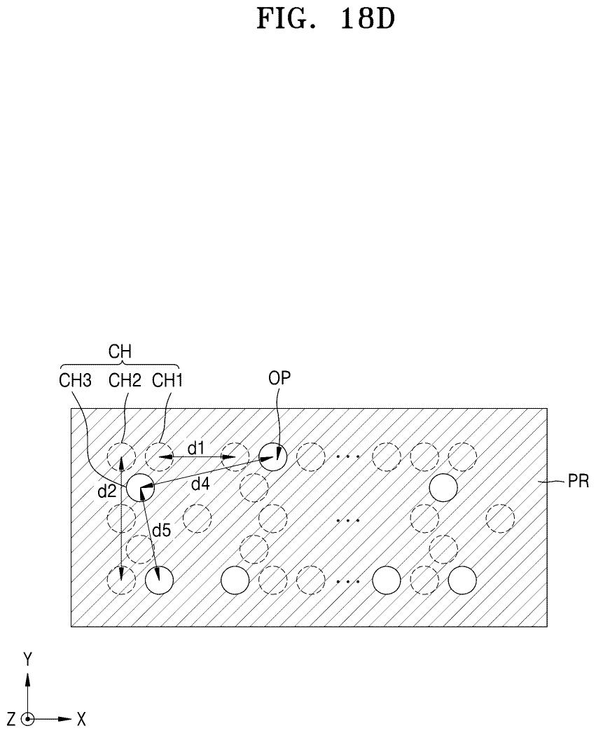

FIG. 18A is an enlarged diagram corresponding to the portion EX1 of FIG. 4, illustrating a layout of contact plugs CP of a semiconductor device according to example embodiments.

Referring to FIG. 18A, the contact plugs CP may include a plurality of first contact plugs CP1, a plurality of second contact plugs CP2, and a plurality of third contact plugs CP3. The first contact plugs CP1 may be arranged apart from each other by a first distance d1 in a horizontal direction. The second contact plugs CP2 may be arranged apart from each other by a second distance d2 in a horizontal direction. Here, the second distance d2 may be greater than or equal to the first distance d1.

In example embodiments, the first contact plugs CP1 may be disposed at the vertices and centers of hexagons, forming a honeycomb pattern. The second contact plugs CP2 and the third contact plugs CP3 may each be disposed at an arbitrary position between the first contact plugs CP1.

In example embodiments, adjacent first and second contact plugs CP1 and CP2 may be arranged apart from each other by a distance less than the first distance d1 in a horizontal direction. Adjacent first and third contact plugs CP1 and CP3 may be arranged apart from each other by a distance less than the first distance d1 in a horizontal direction. Adjacent second and third contact plugs CP2 and CP3 may be arranged apart from each other by a distance less than the first distance d1 in a horizontal direction. According to embodiments, a process of forming a plurality of contact plug holes CH of the semiconductor device 100 may be divided. Therefore, the semiconductor device 100 may include contact plug holes CH arranged apart from each other by a distance less than or equal to a minimum separation distance and, and thus, the degree of integration of the semiconductor device 100 may be improved.

FIGS. 18B to 18D are enlarged plan diagrams corresponding to the portion EX1 of FIG. 4, illustrating a method of manufacturing a semiconductor device according to example embodiments.

FIGS. 18B to 18D illustrate a process of forming a plurality of contact plug holes CH extending in a vertical direction Z by removing portions of a mold stack MS. Descriptions of the same portions as those described with reference to FIGS. 9A to 12 may be omitted.

Referring to FIGS. 18B to 18D, the contact plug holes CH may include a plurality of first contact plug holes CH1, a plurality of second contact plug holes CH2, and a plurality of third contact plug holes CH3. The first contact plug holes CH1 may be arranged apart from each other by a first distance d1 in a horizontal direction. Here, the first distance d1 may refer to a minimum separation distance required to prevent defects in the semiconductor device 100 during processes. In example embodiments, the second contact plug holes CH2 may be arranged apart from each other by a second distance d2 in a horizontal direction. Here, the second distance d2 may be greater than or equal to the first distance d1.

In example embodiments, the first contact plug holes CH1 may be disposed at the vertices and centers of hexagons, forming a honeycomb pattern. The second contact plug holes CH2 and the third contact plug holes CH3 may each be disposed at an arbitrary position between the first contact plug holes CH1.

In example embodiments, in a method of manufacturing the semiconductor device 100 of the present disclosure, contact plug holes CH arranged at a distance less than the first distance d1 in a horizontal direction may not be simultaneously formed by etching. Among the contact plug holes CH, contact plug holes CH arranged apart from each other by at least the first distance d1 in a horizontal direction may be selectively formed at the same time by etching.

Referring to FIG. 18B, in example embodiments, only the first contact plug holes CH1 may be simultaneously formed among the contact plug holes CH. A photoresist pattern PR for forming the first contact plug holes CH1 arranged apart from each other by the first distance d1 in the horizontal direction may include openings OP corresponding to the first contact plug holes CH1. For example, the openings OP may be arranged apart from each other by the first distance d1 in a horizontal direction, forming a honeycomb pattern in which the openings OP are disposed at the vertices and centers of hexagons.

Referring to FIG. 18C, in example embodiments, only the second contact plug holes CH2 may be simultaneously formed among the contact plug holes CH. A photoresist pattern PR for forming the second contact plug holes CH2 arranged apart from each other by the second distance d2 in a horizontal direction may include openings OP corresponding to the second contact plug holes CH2.

Referring to FIG. 18D, in example embodiments, first contact plug holes CH1 selected from the first contact plug holes CH1, second contact plug holes CH2 selected from the second contact plug holes CH2, and third contact plug holes CH3 selected from the third contact plug holes CH3 may be simultaneously formed. In this case, the selected first contact plug holes CH1, the selected second contact plug holes CH2, and the selected third contact plug holes CH3 may be arranged apart from each other by at least the first distance d1 in a horizontal direction.

For example, when arbitrary third contact plug holes CH3 are formed by etching, second contact plug hole CH2 arranged apart from the arbitrary third contact plug holes CH3 by a fourth distance d4 may be formed by etching simultaneously with the arbitrary third contact plug holes CH3. For example, when the arbitrary third contact plug holes CH3 are formed by etching, first contact plug hole CH1 arranged apart from the arbitrary third contact plug holes CH3 by a fifth distance d5 may be formed by etching simultaneously with the arbitrary third contact plug holes CH3. In this case, the fourth distance d4 and the fifth distance d5 may each be greater than or equal to the first distance d1.

First contact plug holes CH1, second contact plug holes CH2, and third contact plug holes CH3 that are to be simultaneously formed by etching may be arbitrarily selected as long as the first contact plug holes CH1, the second contact plug holes CH2, and the third contact plug holes CH3 are arranged apart from each other by at least the first distance d1. That is, first contact plug holes CH1, second contact plug holes CH2, and third contact plug holes CH3 that are simultaneously formed by etching may be arbitrary arranged.

However, when arbitrary first contact plug holes CH1 are formed by etching, second contact plug hole CH2 and/or third contact plug holes CH3 that are arranged apart from the arbitrary first contact plug hole CH1 by a distance less than the first distance d1 may not be formed simultaneously with the arbitrary first contact plug holes CH1.

To form the selected first contact plug holes CH1, the selected second contact plug holes CH2, and the selected third contact plug holes CH3 that are arranged apart from each other by at least the first distance d1 among the contact plug holes CH, a photoresist pattern PR may include openings OP corresponding to the selected first contact plug holes CH1, the selected second contact plug holes CH2, and the selected third contact plug holes CH3. For example, the openings OP may be arbitrarily arranged apart from each other by at least the first distance d1 in a horizontal direction.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
forming a mold stack by alternately forming a plurality of sacrificial layers and a plurality of mold insulating layers on a substrate;
forming a photoresist pattern on the mold stack while exposing portions of the mold stack; and
removing the portions of the mold stack exposed through the photoresist pattern to form a plurality of contact plug holes extending into the mold stack, the plurality of contact plug holes extending in a direction perpendicular to a horizontal plane,
wherein the plurality of contact plug holes comprise:
a plurality of first contact plug holes arranged apart from each other by a first distance in the horizontal plane; and
a plurality of second contact plug holes arranged apart from each other by a second distance greater than or equal to the first distance in the horizontal plane, the plurality of second contact plug holes being arranged apart from the plurality of first contact plug holes by a third distance less than the first distance in the horizontal plane,
wherein, in the removing of the portions of the mold stack, the portions of the mold stack are selectively removed such that a plurality of contact plug holes arranged apart from each other by at least the first distance in the horizontal plane are simultaneously formed among the plurality of first contact plug holes and the plurality of second contact plug holes.

2. The method of claim 1, wherein, in the removing of the portions of the mold stack, the portions of the mold stack are selectively removed such that the plurality of first contact plug holes are simultaneously formed among the plurality of contact plug holes.

3. The method of claim 1, wherein, in the removing of the portions of the mold stack, the portions of the mold stack are selectively removed such that the plurality of second contact plug holes are simultaneously formed among the plurality of contact plug holes.

4. The method of claim 1, wherein the removing of the portions of the mold stack comprises selectively removing the portions of the mold stack such that first contact plug holes selected from the plurality of first contact plug holes and second contact plug holes selected from the plurality of second contact plug holes are simultaneously formed,
wherein the selected first contact plug holes and the selected second contact plug holes are arranged apart from each other by at least the first distance in the horizontal plane.

5. The method of claim 4, wherein the selected first contact plug holes are arranged apart from each other by at least the first distance in the horizontal plane, and
wherein the selected second contact plug holes are arranged apart from each other by at least the first distance in the horizontal plane.

6. The method of claim 1, wherein the plurality of first contact plug holes are arranged in a honeycomb pattern in which the plurality of first contact plug holes are respectively located at vertices and centers of hexagons, and
wherein the plurality of second contact plug holes are located between the plurality of first contact plug holes.

7. The method of claim 1, wherein the plurality of first contact plug holes are respectively located at vertices of tetragons, and
wherein the plurality of second contact plug holes are located between the plurality of first contact plug holes.

8. The method of claim 1, wherein the plurality of contact plug holes further comprise a plurality of third contact plug holes arranged apart from the plurality of first contact plug holes and the plurality of second contact plug holes by a fourth distance less than the first distance in the horizontal plane,
wherein, in the removing of the portions of the mold stack, the portions of the mold stack are selectively removed such that a plurality of contact plug holes arranged apart from each other by at least the first distance in the horizontal plane are simultaneously formed among the plurality of first contact plug holes, the plurality of second contact plug holes, and the plurality of third contact plug holes.

9. The method of claim 1, wherein, in the forming of the photoresist pattern, openings are formed in the photoresist patten to simultaneously expose regions of the mold stack that correspond to a plurality of contact plug holes arranged apart from each other by at least the first distance in the horizontal plane among the plurality of first contact plug holes and the plurality of second contact plug holes.

10. The method of claim 1, further comprising:
forming insulating spacers on the plurality of contact plug holes;
replacing the plurality of sacrificial layers with a plurality of gate electrodes; and
forming a plurality of contact plugs in the plurality of contact plug holes, respectively, and connected to the plurality of gate electrodes, respectively.

11. A method of manufacturing a semiconductor device, the method comprising:
forming a mold stack by alternately forming a plurality of sacrificial layers and a plurality of mold insulating layers on a substrate;
forming a photoresist pattern on the mold stack while exposing portions of the mold stack; and
removing the portions of the mold stack exposed through the photoresist pattern to form a plurality of contact plug holes extending into the mold stack, the plurality of contact plug holes extending in a direction perpendicular to a horizontal plane,
wherein the plurality of contact plug holes comprise:
a plurality of first contact plug holes arranged apart from each other by a first distance in the horizontal plane; and
a plurality of second contact plug holes arranged apart from each other by a second distance greater than or equal to the first distance in the horizontal plane, the plurality of second contact plug holes being arranged apart from the plurality of first contact plug holes by a third distance less than the first distance in the horizontal plane,
wherein the removing of the portions of the mold stack comprises:
removing the portions of the mold stack to simultaneously form the plurality of first contact plug holes and the plurality of second contact plug holes to a preset height; and
selectively removing the portions of the mold stack to simultaneously extend a plurality of contact plug holes arranged apart from each other by at least the first distance in the horizontal plane among the plurality of first contact plug holes and the plurality of second contact plug holes having the preset height.

12. The method of claim 11, wherein, in the selectively removing of the portions of the mold stack, the portions of the mold stack are selectively removed such that the plurality of first contact plug holes are simultaneously formed among the plurality of contact plug holes.

13. The method of claim 11, wherein, in the selectively removing of the portions of the mold stack, the portions of the mold stack are selectively removed such that the plurality of second contact plug holes are simultaneously formed among the plurality of contact plug holes.

14. The method of claim 11, wherein the selectively removing of the portions of the mold stack comprises selectively removing the portions of the mold stack such that first contact plug holes selected from the plurality of first contact plug holes and second contact plug holes selected from the plurality of second contact plug holes are simultaneously formed,
wherein the selected first contact plug holes and the selected second contact plug holes are arranged apart from each other by at least the first distance in the horizontal plane.

15. The method of claim 14, wherein the selected first contact plug holes are arranged apart from each other by at least the first distance in the horizontal plane, and
wherein the selected second contact plug holes are arranged apart from each other by at least the first distance in the horizontal plane.

16. The method of claim 11, wherein the selectively removing of the portions of the mold stack is performed such that the plurality of first contact plug holes and the plurality of second contact plug holes have different levels in the direction perpendicular to the horizontal plane.

17. The method of claim 11, wherein the plurality of first contact plug holes are respectively located at vertices of polygons, and
wherein the plurality of second contact plug holes are located between the plurality of first contact plug holes.

18. The method of claim 11, wherein the plurality of contact plug holes further comprise a plurality of third contact plug holes arranged apart from the plurality of first contact plug holes and the plurality of second contact plug holes by a fourth distance less than the first distance in the horizontal plane,
wherein, in the removing of the portions of the mold stack, the portions of the mold stack are removed to simultaneously form the plurality of first contact plug holes, the plurality of second contact plug holes, and the plurality of third contact plug holes to the preset height, and
wherein in the selectively removing of the portions of the mold stack, the portions of the mold stack are selectively removed to simultaneously extend a plurality of contact plug holes arranged apart from each other by at least the first distance in the horizontal plane among the plurality of first contact plug holes, the plurality of second contact plug holes, and the plurality of third contact plug holes.

19. A semiconductor device comprising:
a peripheral circuit structure; and
a cell structure on the peripheral circuit structure and comprising a cell region and a connection region,
wherein the cell structure comprises:
a plurality of gate electrodes and a plurality of mold insulating layers that are alternately arranged in the cell region and the connection region in a vertical direction perpendicular to an upper surface of the peripheral circuit structure;
a channel structure extending through the plurality of gate electrodes in the vertical direction; and
a plurality of contact plugs electrically connected to the plurality of gate electrodes in the connection region,
wherein the plurality of contact plugs comprise:
a plurality of first contact plugs arranged apart from each other by a first distance in a horizontal plane parallel to the upper surface of the peripheral circuit structure; and
a plurality of second contact plugs arranged apart from each other by a second distance greater than or equal to the first distance in the horizontal plane, the plurality of second contact plugs being arranged apart from the plurality of first contact plugs by a third distance less than the first distance in the horizontal plane.

20. The semiconductor device of claim 19, wherein the plurality of first contact plugs are respectively arranged at vertices of polygons, and
wherein the plurality of second contact plugs are arranged between the plurality of first contact plugs.
